(19) United States
(12) Patent Application Publication
(10) Pub. No.: US 2025/0267997 A1
(43) Pub. Date: Aug. 21, 2025

(54) DISPLAY DEVICE

(71) Applicant: Samsung Display Co., LTD., Yongin-si (KR)

(72) Inventors: Do Yeong PARK, Yongin-si (KR); Ki Hyun PYO, Yongin-si (KR); Sung Chul HONG, Yongin-si (KR)

(73) Assignee: Samsung Display Co., LTD., Yongin-si (KR)

(21) Appl. No.: 18/891,042

(22) Filed: Sep. 20, 2024

(30) Foreign Application Priority Data
Feb. 16, 2024 (KR) 10-2024-0022881

(51) Int. Cl. H01L 33/62; H01L 25/16

(52) U.S. Cl. CPC H10H 20/857; H01L 25/167

(57) ABSTRACT

A display device includes a pixel circuit layer, anodes disposed on the pixel circuit layer and spaced apart from each other in a first diagonal direction and a second diagonal direction intersecting the first diagonal direction, a cathode disposed on the pixel circuit layer and spaced apart from the anodes, and light emitting elements, wherein the light emitting elements are electrically connected to the respective anodes and the cathode.

### CROSS-REFERENCE TO RELATED APPLICATION(S)

This application claims priority to and benefits of Korean Patent Application No. 10-2024-0022881 under 35 U.S.C. § 119, filed on Feb. 16, 2024, in the Korean Intellectual Property Office, the entire contents of which are incorporated herein by reference.

### BACKGROUND

### 1. Technical Field

Embodiments relate to a display device.

### 2. Description of the Related Art

As information technology develops, the importance of a display device, which is a connection medium between a user and information, has been highlighted. As a result, a use of a display device such as a liquid crystal display device and an organic light emitting display device is increasing.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device capable of mitigating voltage drop (or IR drop) and power consumption.

However, embodiments are not limited to those set forth herein. The above and other embodiments will become more apparent to one of ordinary skill in the art to which the disclosure pertains by referencing the detailed description of the disclosure given below.

According to an embodiment, a display device may include a pixel circuit layer, anodes disposed on the pixel circuit layer and spaced apart from each other in a first diagonal direction and a second diagonal direction intersecting the first diagonal direction, a cathode disposed on the pixel circuit layer and spaced apart from the anodes, and light emitting elements, wherein the light emitting elements are electrically connected to the anodes and the cathode.

The pixel circuit layer may include transistors, a first passivation layer including first contact holes, conductive patterns arranged on the first passivation layer in a first direction, and extending in a second direction intersecting the first direction, and a second passivation layer including second contact holes.

In each pixel, the first contact holes may have a same position in the second direction, and the second contact holes may have different positions in the second direction.

The anodes and the cathode may be disposed on a same plane.

The anodes may be arranged in a zigzag pattern in the first diagonal direction and the second diagonal direction.

The cathode may have a diagonal mesh structure.

The cathode may include a first line component extending in the first diagonal direction and disposed in the second diagonal direction and a second line component extending in the second diagonal direction and disposed in a zigzag pattern in the first diagonal direction and the second diagonal direction.

The cathode may surround the anodes in each sub-pixel.

Each of the light emitting elements may include a flip-chip-type light emitting element.

The light emitting elements may be arranged in the first diagonal direction to have constant distances between the light emitting elements.

The light emitting elements may be arranged in a zigzag pattern in the first diagonal direction and the second diagonal direction.

The cathode may surround the anodes in each pixel.

Light emitting elements included in each pixel may be arranged in the first diagonal direction to have first distances between the light emitting elements included in each pixel. Light emitting elements respectively included in adjacent pixels may be arranged in the first diagonal direction to have a second distance between the light emitting elements respectively included in adjacent pixels, which is different from the first distances.

The light emitting elements may be arranged in a first direction and a second direction intersecting the first direction to have constant distances between the light emitting elements.

The display device may further include color filters respectively disposed on the light emitting elements.

A center portion of each of the color filters may be aligned with a center portion of a corresponding one of the light emitting elements.

The light emitting elements may include first light emitting elements that emit light in a first color, second light emitting elements that emit light in a second color, and third light emitting elements that emit light in a third color. The color filters may include first color filters respectively disposed on the first light emitting elements, second color filters respectively disposed on the second light emitting elements, and third color filters respectively disposed on the third light emitting elements.

The size of each of the second color filters may be greater than that of each of the first color filters, and the size of each of the first color filters may be greater than that of each of the third color filters.

Each of the color filters may have a polygonal shape.

Each of the light emitting elements may include a lateral-chip-type light emitting element.

The display device may further include a reflective electrode disposed in a diagonal mesh structure on the cathode, and a transparent electrode disposed in a diagonal mesh structure on the reflective electrode, and electrically connected to the light emitting elements.

According to an embodiments, a display device may be capable of mitigating voltage drop (IR drop) and power consumption.

However, effects of the disclosure are not limited to the above-described effects, and may be variously expanded within a range that does not deviate from the spirit and scope of the disclosure.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating a display device according to an embodiment.

FIG. 2 is a schematic block diagram illustrating any one of sub-pixels of FIG. 1 according to an embodiment.

FIG. 3 is a schematic diagram of an equivalent circuit of the sub-pixel of FIG. 2 according to an embodiment.

FIG. 4 is a schematic plan view illustrating a display panel of FIG. 1 according to an embodiment.

FIG. 5 is a schematic sectional view illustrating a display panel of FIG. 4 according to an embodiment.

FIG. 6 is a schematic plan view illustrating a display panel of FIG. 4 according to an embodiment.

FIG. 7 is a schematic sectional view taken along line I-I′ of FIG. 6.

FIG. 8 is a schematic sectional view taken along line II-II′ of FIG. 6.

FIG. 9 is a schematic plan view illustrating a pixel circuit layer according to an embodiment.

FIG. 10 is a schematic sectional view taken along line III-III′ of FIG. 9.

FIG. 11 is a schematic sectional view taken along line IV-IV′ of FIG. 9.

FIG. 12 is a schematic sectional view taken along line V-V′ of FIG. 9.

FIG. 13 is a schematic plan view illustrating a display panel of FIG. 4 according to an embodiment.

FIG. 14 is a schematic plan view illustrating a display panel of FIG. 1 according to an embodiment.

FIG. 15 is a schematic plan view illustrating a display panel of FIG. 14 according to an embodiment.

FIG. 16 is a schematic plan view illustrating a color filter layer according to an embodiment.

FIG. 17 is a schematic plan view illustrating a color filter layer according to an embodiment.

FIG. 18 is a schematic plan view illustrating a color filter layer according to an embodiment.

FIG. 19 is a schematic plan view illustrating a display panel of FIG. 4 according to an embodiment.

FIG. 20 is a schematic plan view illustrating anodes and a cathode illustrated in FIG. 19.

FIG. 21 is a schematic plan view illustrating first reflective electrodes and a second reflective electrode illustrated in FIG. 19.

FIG. 22 is a schematic plan view illustrating light emitting elements, first transparent electrodes, and a second transparent electrode illustrated in FIG. 19.

FIG. 23 is a schematic sectional view taken along line VI-VI′ of FIG. 19.

FIG. 24 is a schematic block diagram illustrating a display system according to an embodiment.

FIGS. 25 to 28 are schematic perspective views illustrating application examples of the display system of FIG. 24.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments of the disclosure are described in detail with reference to the accompanying drawings.

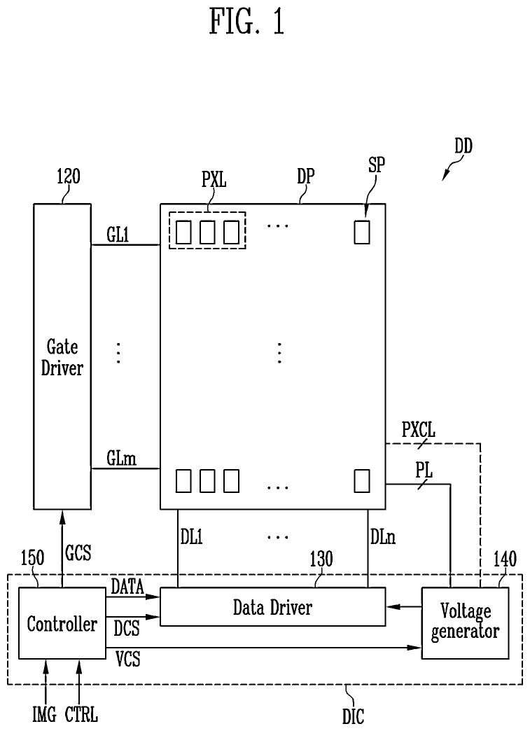

FIG. 1 is a schematic block diagram illustrating a display device DD according to an embodiment.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light in two or more colors. For example, each of the sub-pixels SP may generate light in a color such as red, green, blue, cyan, magenta, or yellow.

Two or more sub-pixels among the sub-pixels SP may form a pixel PXL. For example, the pixel PXL may include three sub-pixels, as illustrated in FIG. 1. For example, the pixel PXL may emit light of various colors and various luminances according to the combination of light emitted from the sub-pixels included therein.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. In embodiments, the gate control signal GCS may include a start signal instructing each frame to start, a horizontal synchronization signal, and the like.

The gate driver 120 may be disposed on a side of the display panel DP. However, embodiments are not limited to the aforementioned example. For example, the gate driver 120 may be divided into two or more drivers that are physically and/or logically distinguished from each other. The drivers may be disposed on a first side of the display panel DP and a second side of the display panel DP opposite to the first side. For example, the gate driver 120 may be disposed around the display panel DP in various forms according to embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may apply, using received voltages, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the first to n-th data lines DL1 to DLn. Hence, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 may generate a plurality of voltages and provide the generated voltages to components of the display device DD such as the gate driver 120, the data driver 130, and the controller 150. The voltage generator 140 may receive an input voltage from an external device of the display device DD and generate a plurality of voltages by regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from an external device to the display device DD.

For example, the voltage generator 140 may provide various voltages and/or signals. For example, the voltage generator 140 may provide one or more initialization voltages to be applied to the sub-pixels SP. For example, during a sensing operation for sensing electrical characteristics of transistors and/or light emitting elements of the sub-pixels SP, a certain reference voltage may be applied to each of the first to n-th data lines DL1 to DLn. The voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through pixel control lines PXCL. Although in FIG. 1 there is illustrated the case where the pixel control lines PXCL are connected between the voltage generator 140 and the display panel DP, embodiments are not limited thereto. For example, the pixel control lines PXCL may be connected between the gate driver 120 and the display panel DP. For example, the pixel control signals may be transmitted from the voltage generator 140 to the pixel control lines PXCL through the gate driver 120.

The controller 150 may control overall operations of the display device DD. The controller 150 may receive input image data IMG and a control signal CTRL corresponding thereto from an external device. The controller 150 may provide a gate control signal GCS, a data control signal DCS, and a voltage control signal VCS, in response to the control signal CTRL.

The controller 150 may convert the input image data IMG to be suitable for the display device DD or the display panel DP and output image data DATA. In embodiments, the controller 150 may align the input image data IMG to be suitable for the sub-pixels SP in a row (or in a single row) and output the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. For example, the data driver 130, the voltage generator 140, and the controller 150 may be components that are functionally separated from each other in the single driver integrated circuit DIC. In other embodiments, at least one of the data driver 130, the voltage generator 140, and the controller 150 may be provided as a component separated from the driver integrated circuit DIC.

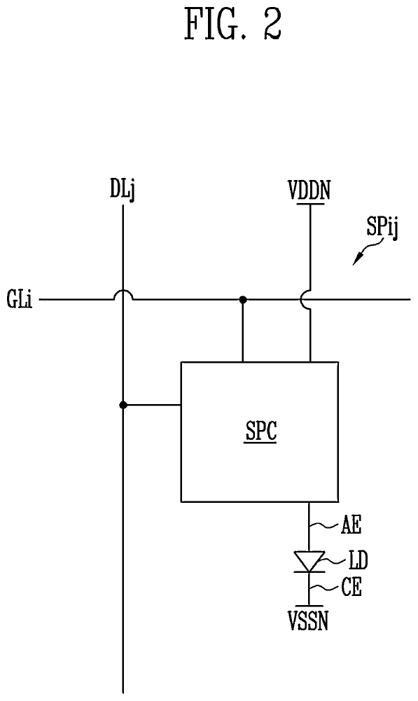

FIG. 2 is a schematic block diagram illustrating any one of sub-pixels SPij of FIG. 1 according to an embodiment. In FIG. 2, there is illustrated a sub-pixel SPij disposed on an i-th row (where i is an integer identical to or greater than 1 and identical to or less than m) and a j-th column (where j is an integer identical to or greater than 1 and identical to or less than n) among the sub-pixels SP of FIG. 1.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 to receive a first power voltage. The second power voltage node VSSN may be connected to another one of the power lines PL of FIG. 1 to receive a second power voltage. The first power voltage may have a voltage level higher than the second power voltage.

The light emitting element LD may be connected between an anode AE and a cathode CE. The anode AE may be connected to the first power voltage node VDDN through the sub-pixel circuit SPC. For example, the anode AE may be connected to the first power voltage node VDDN through one or more transistors included in the sub-pixel circuit SPC. The cathode CE may be connected to the second power voltage node VSSN. The light emitting element LD may emit light based on current flowing from the anode AE to the cathode CE.

The sub-pixel circuit SPC may be connected both to an i-th gate line GLi among the first to m-th gate lines GL1 to GLm of FIG. 1 and to a j-th data line DLj among the first to n-th data lines DL1 to DLn of FIG. 1. In response to a gate signal received through the i-th gate line GLi, the sub-pixel circuit SPC may control the light emitting element LD to emit light based on a data signal received through the j-th data line DLj. In embodiments, the sub-pixel circuit SPC may be further connected to the pixel control lines PXCL of FIG. 1. For example, the sub-pixel circuit SPC may further control the light emitting element LD in response to pixel control signals received through the pixel control lines PXCL.

For the sake of the aforementioned operations, the sub-pixel circuit SPC may include circuit elements, for example, transistors and one or more capacitors.

The transistors of the sub-pixel circuit SPC may include p-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, or the like.

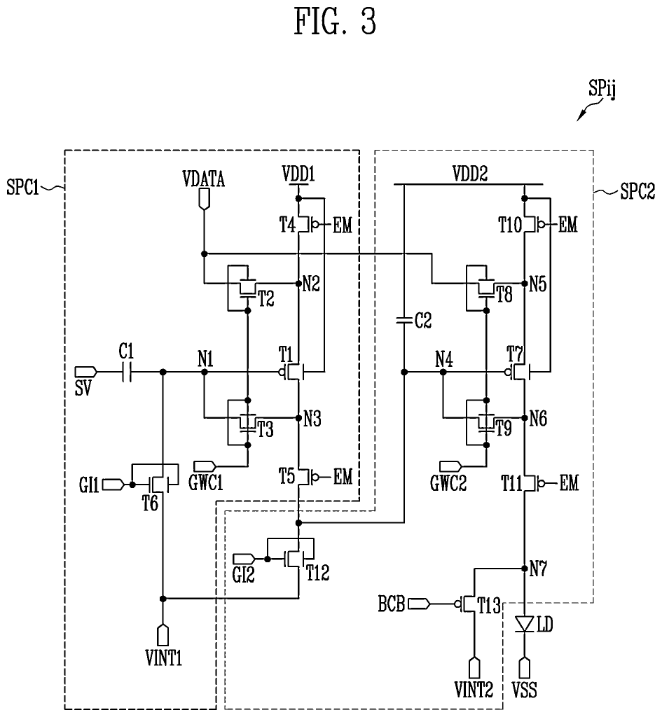

FIG. 3 is a schematic diagram of an equivalent circuit of the sub-pixel SPij of FIG. 2 according to an embodiment.

Referring to FIG. 3, the sub-pixel SPij may include a light emitting element LD, a first sub-pixel circuit SPC1 that controls an emission time of the light emitting element LD, and a second sub-pixel circuit SPC2 that provides driving current to the light emitting element LD.

For example, the first sub-pixel circuit SPC1 may include: a first transistor T1 including a control electrode connected to a first node N1, a first electrode connected to a second node N2, and a second electrode connected to a third node N3; a first capacitor C1 including a first electrode that receives a sweep voltage SV, and a second electrode connected to the first node N1; a second transistor T2 including a control electrode that receives a first write gate signal GWC1, a first electrode that receives a data voltage VDATA, and a second electrode connected to the second node N2; a third transistor T3 including a control electrode that receives the first write gate signal GWC1, a first electrode connected to the third node N3, and a second electrode connected to the first node N1; a fourth transistor T4 including a control electrode that receives an emission signal EM, a first electrode that receives a 1-1-th power voltage VDD1, and a second electrode connected to the second node N2; a fifth transistor T5 including a control electrode that receives the emission signal EM, a first electrode connected to the third node N3, and a second electrode connected to a second sub-pixel circuit SPC2 (e.g., a fourth node N4); and a sixth transistor T6 including a control electrode that receives the first initialization gate signal GI1, a first electrode that receives a first initialization voltage VINT1, and a second electrode connected to the first node N1.

For example, the second sub-pixel circuit SPC2 may include: a seventh transistor T7 including a control electrode connected to the fourth node N4, a first electrode connected to a fifth node N5, and a second electrode connected to a sixth node N6; a second capacitor C2 including a first electrode that receives a 1-2-th power voltage VDD2, and a second electrode connected to the fourth node N4; an eighth transistor T8 including a control electrode that receives a second write gate signal GWC2, a first electrode that receives the data voltage VDATA, and a second electrode connected to the fifth node N5; a ninth transistor T9 including a control electrode that receives the second write gate signal GWC2, a first electrode connected to the sixth node N6, and a second electrode connected to the fourth node N4; a tenth transistor T10 including a control electrode that receives the emission signal EM, a first electrode that receives the 1-2-th power voltage VDD2, and a second electrode connected to the fifth node N5; an eleventh transistor T11 including a control electrode that receives the emission signal EM, a first electrode connected to the sixth node N6, and a second electrode connected to a seventh node N7; a twelfth transistor T12 including a control electrode that receives a second initialization gate signal GI2, a first electrode that receives the first initialization voltage VINT1, and a second electrode connected to the fourth node N4; and a thirteenth transistor T13 including a control electrode that receives a bias gate signal BCB, a first electrode that receives a second initialization voltage VINT2, and a second electrode connected to the seventh node N7.

For example, the light emitting element LD may include a first electrode (e.g., the anode AE of FIG. 2) connected to the seventh node N7, and a second electrode (e.g., the cathode CE of FIG. 2) that receives a second power voltage VSS.

The first, fourth, fifth, seventh, tenth, eleventh, and thirteenth transistors T1, T4, T5, T7, T10, T11, and T13 may be P-type transistors. The second, third, sixth, eighth, ninth, and twelfth transistors T2, T3, T6, T8, T9, and T12 may be N-type transistors. However, embodiments are not limited to the aforementioned example, and the P-type transistors may be replaced with N-type transistors. The N-type transistors may be replaced with P-type transistors.

In an embodiment, the first transistor T1 may include a back gate electrode that receives the 1-1-th power voltage VDD1. The second transistor T2 may include a back gate electrode connected to the control electrode of the second transistor T2. The third transistor T3 may include a back gate electrode connected to the control electrode of the third transistor T3. The sixth transistor T6 may include a back gate electrode that receives the first initialization gate signal GI1.

In an embodiment, the seventh transistor T7 may include a back gate electrode that receives the 1-2-th power voltage VDD2. The eighth transistor T8 may include a back gate electrode connected to the control electrode of the eighth transistor T8. The ninth transistor T9 may include a back gate electrode connected to the control electrode of the ninth transistor T9. The twelfth transistor T12 may include a back gate electrode that receives the second initialization gate signal GI2.

The sixth transistor T6 may provide the first initialization voltage VINT1 to the first node N1 in response to the first initialization gate signal GI1. Accordingly, the voltage of the first node N1 may be initialized to the first initialization voltage VINT1.

The second transistor T2 may provide the data voltage VDATA to the second node N2 in response to the first write gate signal GWC1. The third transistor T3 may diode-connect the first transistor T1 in response to the first write gate signal GWC1. Accordingly, a voltage compensated for by a threshold voltage of the first transistor T1 may be applied to the first node N1.

The fourth transistor T4 may provide the first power voltage VDD1 to the first transistor T1 in response to the emission signal EM. The fifth transistor T5 may provide current generated by the first transistor T1 to the fourth node N4 in response to the emission signal EM. For example, the sweep voltage SV may be reduced, and a time point at which the first transistor T1 is turned on may vary according to the magnitude of the data voltage VDATA. Accordingly, a time point at which the voltage of the fourth node N4 increases may vary, and a time point at which the seventh transistor T7 is turned off may vary. For example, the first sub-pixel circuit SPC1 may control the emission time of the light emitting element LD by adjusting the time point at which the seventh transistor T7 that provides driving current to the light emitting element LD is turned off. The luminance (e.g., grayscale expression) of the light emitting element LD may vary according to the emission time.

In an embodiment, the sweep voltage SV, the second write gate signal GWC2, the emission signal EM, the bias gate signal BCB, the first initialization gate signal GI1, and the second initialization gate signal GI2 may be pixel control signals. For example, the pixel control signals may be provided (e.g., identically provided) to the sub-pixels SP (refer to FIG. 1).

In an embodiment, the first write gate signal GWC1 may be provided to the sub-pixels SP through the first to m-th gate lines GL1 to GLm (refer to FIG. 1). For example, the first write gate signal GWC1 may be sequentially provided to each of the gate lines GL1 to GLm (refer to FIG. 1).

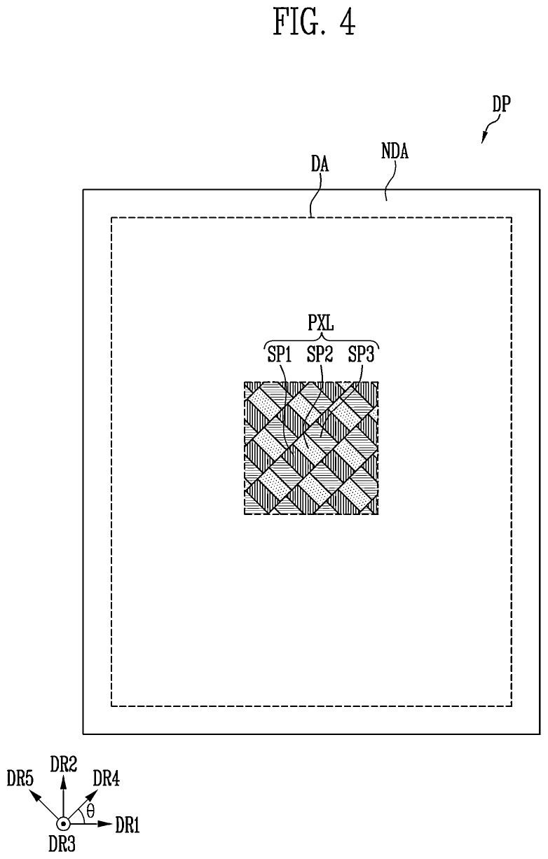

FIG. 4 is a schematic plan view illustrating a display panel DP of FIG. 1 according to an embodiment.

Referring to FIG. 4, the display panel DP may include a display area DA and a non-display area NDA. The display panel DP may display an image through the display area DA. The non-display area NDA may be disposed around the display area DA. For example, the display area DA (or the non-display area NDA) may include first sides (or short sides) extending in a first direction DR1 and second sides (or long sides) extending in a second direction DR2.

The display panel DP may include first to third sub-pixels SP1 to SP3 in the display area DA. The first to third sub-pixels SP1 to SP3 may be arranged in a first diagonal direction DR4 and a second diagonal direction DR5 intersecting the first diagonal direction DR4. For example, the first diagonal direction DR4 may extend between the first direction DR1 and the second direction DR2, and the second diagonal direction DR5 may extend between the second direction DR2 and a direction opposite to the first direction DR1. For example, the first to third sub-pixels SP1 to SP3 may be arranged in a zigzag pattern in the first diagonal direction DR4 and the second diagonal direction DR5. For example, the first to third sub-pixels SP1 to SP3 may be arranged in a diagonal pattern. The arrangement of the first to third sub-pixels SP1 to SP3 may be changed according to embodiments. The first direction DR1 may refer to a row direction, and the second direction DR2 may refer to a column direction.

The first to third sub-pixels SP1 to SP3 may form a single pixel PXL. Although FIG. 4 illustrates that the pixel PXL includes three sub-pixels SP1 to SP3, embodiments are not limited thereto. For example, the pixel PXL may include two sub-pixels. Hereinafter, for convenience of explanation, it is assumed that the pixel PXL includes first to third sub-pixels SP1 to SP3.

Each of the first to third sub-pixels SP1 to SP3 may generate light of one among various colors such as red, green blue, cyan, magenta, and yellow. Hereinafter, for clear and concise description, it is assumed that the first sub-pixel SP1 generates light in red, the second sub-pixel SP2 generates light in green, and the third sub-pixel SP3 generates light in blue.

Each of the first to third sub-pixels SP1 to SP3 may include at least one light emitting element that generates light. In embodiments, the light emitting elements of the first to third sub-pixels SP1 to SP3 may generate light in the same color. For example, the light emitting elements of the first to third sub-pixels SP1 to SP3 may generate light in blue. In other embodiments, the light emitting elements of the first to third sub-pixels SP1 to SP3 may generate light in different colors. For example, the light emitting elements of the first to third sub-pixels SP1 to SP3 may respectively generate light in red, green, and blue.

As a display panel DP, a self-luminous display panel such as an LED display panel using a micro-scale or nano-scale light emitting diode as a light emitting element, and an organic light emitting display panel (OLED panel) using an organic light emitting diode as a light emitting element may be used.

Components for controlling the sub-pixels SP may be disposed in the non-display area NDA. Lines connected to the sub-pixels SP, for example, the first to m-th gate lines GL1 to GLm, the first to n-th data lines DL1 to DLn, the power lines PL, and the pixel control lines PXCL of FIG. 1, may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. For example, the data driver 130, the voltage generator 140, and the controller 150 may be implemented as the driver integrated circuit DIC of FIG. 1 that is separated from the display panel DP. The driver integrated circuit DIC may be connected to the lines disposed in the non-display area NDA. In other embodiments, the gate driver 120 along with the data driver 130, the voltage generator 140, and the controller 150 may be implemented as a single integrated circuit that is separated from the display panel DP.

In embodiments, the display area DA may have various shapes. The display area DA may have a closed-loop shape, including linear and/or curved sides. For example, the display area DA may have shapes such as polygons, circles, semicircles, ellipses, and the like.

In embodiments, the display panel DP may have a planar display surface. In embodiments, the display panel DP may have a display surface that is at least partially rounded. In embodiments, the display panel DP may be bendable, foldable, or rollable. In the aforementioned cases, the display panel DP and/or a substrate of the display panel DP may include materials having flexible properties.

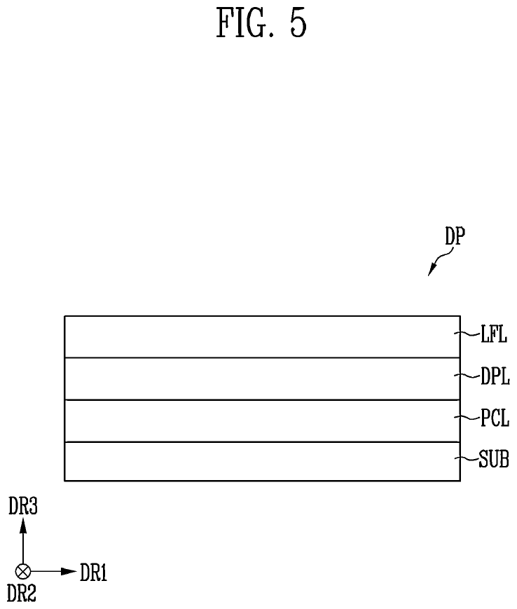

FIG. 5 is a schematic sectional view illustrating a display panel DP of FIG. 4 according to an embodiment.

Referring to FIG. 5, the display panel DP may include a substrate SUB, and a pixel circuit layer PCL, a display element layer DPL, and a light functional layer LFL that are sequentially stacked on the substrate SUB in a third direction DR3 intersecting the first and second directions DR1 and DR2.

The substrate SUB may be made of insulating material such as glass or resin. For example, the substrate SUB may include a glass substrate. As another example, the substrate SUB may include a polyimide (PI) substrate. As another example, the substrate SUB may include a silicon wafer substrate formed by a semiconductor process.

In embodiments, the substrate SUB may be made of material having flexibility so as to be bendable or foldable, and may have a single-layer structure or a multilayer structure. For instance, the material having flexibility may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns disposed between the insulating layers. The conductive patterns of the pixel circuit layer PCL may function as circuit elements, lines, or the like.

The circuit elements of the pixel circuit layer PCL may include the respective sub-pixel circuits SPC (refer to FIG. 2) of the sub-pixels SP (refer to FIG. 1). For example, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines needed to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may convert the wavelength (or color) of light emitted from the display element layer DPL. The light functional layer LFL may further include light scattering patterns having scattering particles. In another example, the light conversion patterns and the light scattering patterns may be omitted.

The light functional layer LFL may further include a color filter layer including color filters. Each of the color filters may selectively transmit light of a specific wavelength (or specific color). In another example, the color filter layer may be omitted.

A window may be provided (or disposed) on the light functional layer LFL to protect an exposed surface (or upper surface) of the display panel DP. The window may protect the display panel DP from an external impact. The window may be connected to the light functional layer LFL by an optically transparent adhesive (or bonding) agent. The window may have a multilayer structure selected from among a glass substrate, a plastic film, and a plastic substrate. The multilayer structure may be formed by a successive process or an adhesion process using an adhesive layer. The entirety or portion of the window may have flexibility.

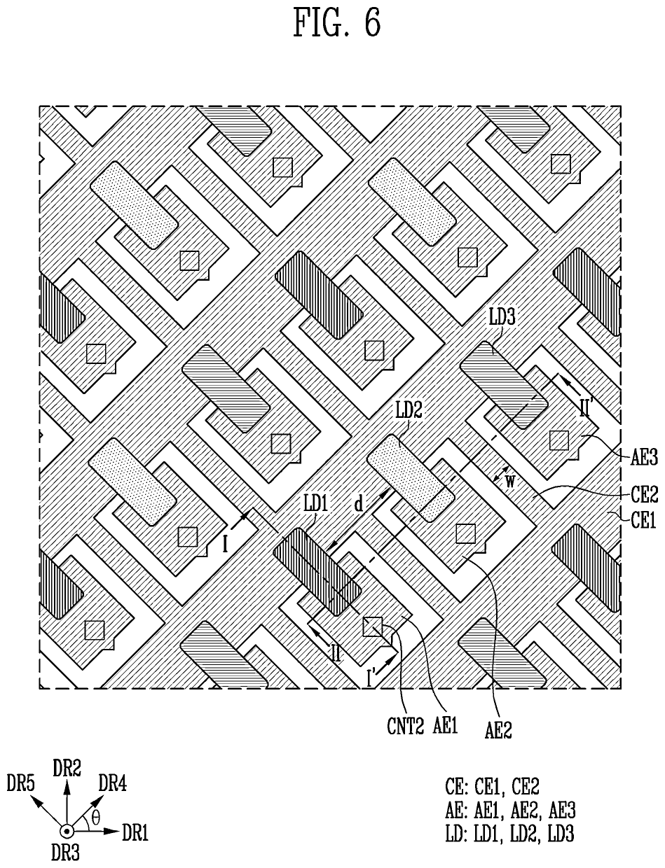

FIG. 6 is a schematic plan view illustrating a display panel DP of FIG. 4 according to an embodiment.

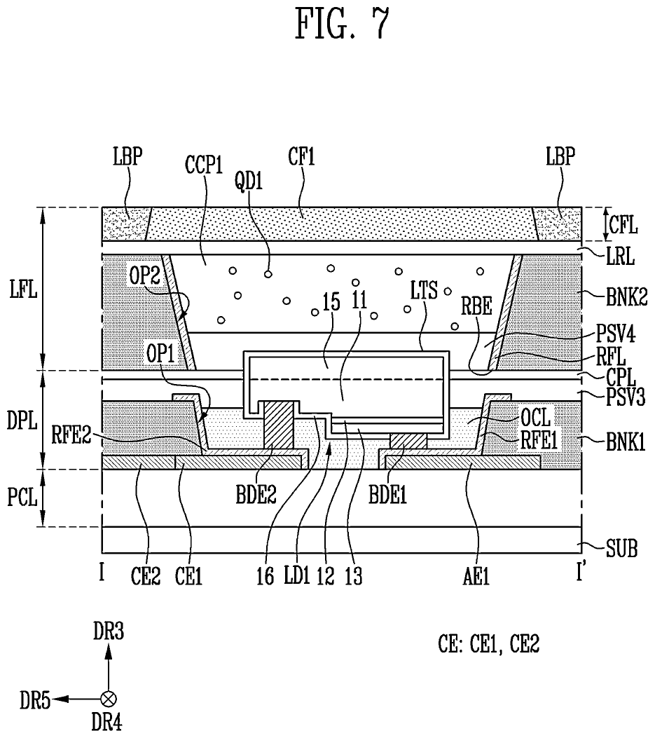

Referring to FIG. 6, anodes AE may be provided (or disposed) on the pixel circuit layer PCL (refer to FIG. 7). The anodes AE may be connected (e.g., electrically connected) to respective light emitting elements LD. The anodes AE may include first anodes AE1, second anodes AE2, and third anodes AE3. The first anodes AE1 may be connected (e.g., electrically connected) to respective first light emitting elements LD1. The second anodes AE2 may be connected (e.g., electrically connected) to respective second light emitting elements LD2. The third anodes AE3 may be connected (e.g., electrically connected) to respective third light emitting elements LD3.

The anodes AE may be spaced apart from each other in the first diagonal direction DR4 and the second diagonal direction DR5 intersecting the first diagonal direction DR4. For example, the anodes AE may be arranged in a zigzag pattern in the first diagonal direction DR4 and the second diagonal direction DR5. Since the anodes AE are arranged in the first and second diagonal directions DR4 and DR5, distances between the anodes AE may increase. For example, the distances between the anodes AE may be wider in the case where the anodes AE are arranged in the first diagonal direction DR4 and the second diagonal direction DR5 (e.g., diagonal arrangement), compared to the case where the anodes AE are arranged in the first direction DR1 and the second direction DR2 intersecting the first direction DR1 (e.g., stripe arrangement). As the distances between the anodes AE increase, space where the cathode CE is disposed between the anodes AE may be provided. In embodiments, an angle (θ) of the first diagonal direction DR4 may be an angle between the first direction DR1 (e.g., the extending direction of the first sides of the display area DA of the display panel DP) and the second diagonal direction DR4 (e.g., the arrangement direction of the anodes AE). However, the angle (θ) of the first diagonal direction DR4 in which the anodes AE are arranged is not limited thereto. Hereinafter, for convenience of explanation, it is assumed that the angle (θ) of the first diagonal direction DR4 is about 45°.

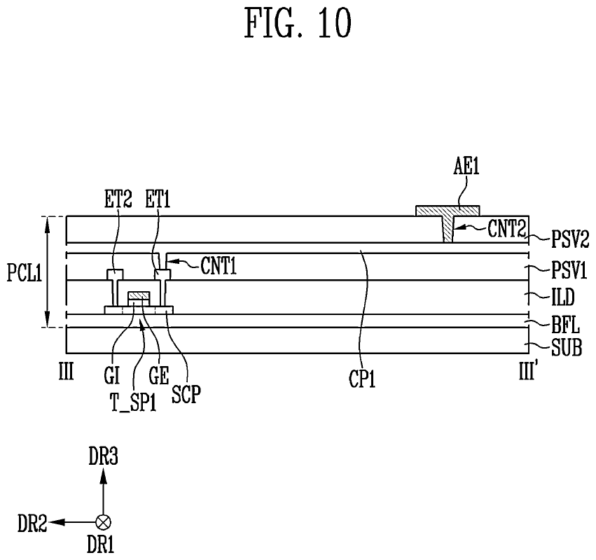

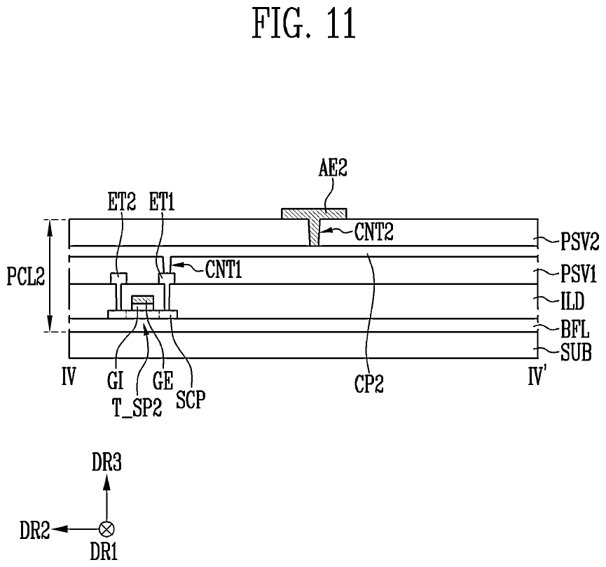

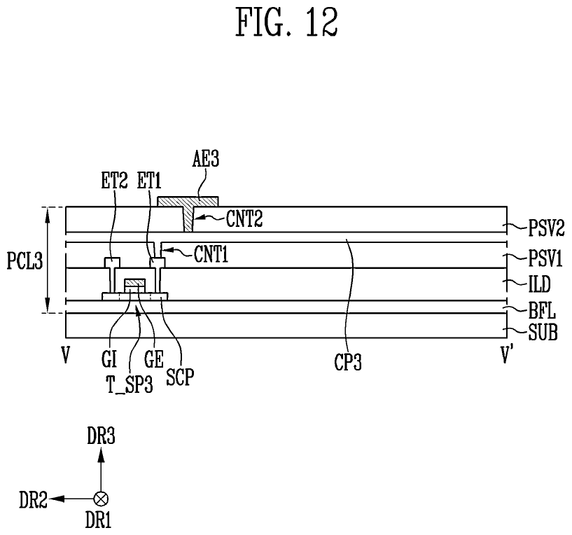

The anodes AE may be connected (e.g., electrically connected) to the pixel circuit layer PCL through respective second contact holes CNT2. For example, the first anodes AE1 may be connected (e.g., electrically connected) to a first conductive pattern CP1 (refer to FIG. 10) through the respective corresponding second contact holes CNT2. Furthermore, the second anodes AE2 may be connected (e.g., electrically connected) to a second conductive pattern CP2 (refer to FIG. 11) through the respective corresponding second contact holes CNT2. For example, the third anodes AE3 may be connected (e.g., electrically connected) to a third conductive pattern CP3 (refer to FIG. 12) through the respective corresponding second contact holes CNT2.

The second contact holes CNT2 may be positioned at regular intervals (or constant distances) in the first diagonal direction DR4. For example, the distance between the second contact holes CNT2 in the first direction DR1 may be the same as the distance between the second contact holes CNT2 in the second direction DR2. However, embodiments are not limited to the aforementioned example.

The cathode CE may be provided (or disposed) on the pixel circuit layer PCL. The cathode CE may be connected (e.g., electrically connected) to the light emitting elements LD. For example, the first light emitting elements LD1 may be connected (e.g., electrically connected) to the cathode CE. Furthermore, the second light emitting elements LD2 may be connected (e.g., electrically connected) to the cathode CE. For example, the third light emitting elements LD3 may be connected (e.g., electrically connected) to the cathode CE. In an embodiment, the cathode CE and the anodes AE may be provided (or disposed) on the same plane. The cathode CE may be spaced apart from the anodes AE.

The cathode CE may have a diagonal mesh structure. For example, the cathode CE may include first line components CE1 that extend in the first diagonal direction DR4 and are arranged in the second diagonal direction DR5, and second line components CE2 that extend in the second diagonal direction DR5 and are arranged in the first diagonal direction DR4 and the second diagonal direction DR5. The second line components CE2 may be arranged in a zigzag pattern in the first diagonal direction DR4 and the second diagonal direction DR5. The first line components CE1 may be spaced apart from the light emitting elements LD in the second diagonal direction DR5. The second line components CE2 may be spaced apart from the light emitting elements LD in the first diagonal direction DR4.

Since the space is ensured between the anodes AE, the cathode CE (or the second line components CE2) may be additionally positioned between the anodes AE. For example, the cathode CE may decrease in resistance, so that voltage drop (IR drop) may be mitigated (or reduced), whereby reducing power consumption. For example, the power consumption may be significantly reduced in the case of application of a pulse width modulation (PWM) pixel circuit (refer to FIG. 3) that uses high current. Furthermore, the voltage drop (e.g., IR drop) may be mitigated (or reduced) by reducing the resistance of the cathode CE without using an additional line layer. Hence, process costs may be reduced, and process efficiency and integration density may be enhanced.

In an embodiment, the cathode CE may surround (or enclose) each of the anodes AE. For example, the cathode CE may surround (or enclose) each of the first anodes AE1. Furthermore, the cathode CE may surround (or enclose) each of the second anodes AE2. Furthermore, the cathode CE may surround (or enclose) each of the third anodes AE3. The cathode CE having a diagonal mesh structure may include openings. The first to third anodes AE1 to AE3 may be respectively disposed in the openings. The openings may refer to space formed by intersection of the first line components CE1 and the second line components CE2. For example, the cathode CE may surround (or enclose) the anodes AE in a sub-pixel (or in a single sub-pixel). For example, each of the first to third sub-pixels SP1 to SP3 (refer to FIG. 4) may include one second line component CE2. Therefore, each of the pixels PXL (refer to FIG. 4) may have three second line components CE2.

The light emitting elements LD may be provided (or disposed) on the respective anodes AE and the cathode CE. For example, the first light emitting elements LD1 may be disposed on the respective first anodes AE1 and the cathode CE. Furthermore, the second light emitting elements LD2 may be disposed on the respective second anodes AE2 and the cathode CE. For example, the third light emitting elements LD3 may be disposed on the respective third anodes AE3 and the cathode CE. The first to third light emitting elements LD1 to LD3 may be connected (e.g., electrically connected) to the first line component CE1 of the cathode CE.

In an embodiment, each of the light emitting elements LD may be of a flip chip type. For example, the light emitting elements LD may be connected (e.g., electrically connected), on lower portions thereof, to the respective anodes AE and the cathode CE. The foregoing structure will be described herein below with reference to FIG. 7.

In an embodiment, the light emitting elements LD may be spaced apart from each other in the first diagonal direction DR4 and the second diagonal direction DR5 intersecting the first diagonal direction DR4. For example, the first light emitting elements LD1 may be arranged in a zigzag pattern in the first diagonal direction DR4 and the second diagonal direction DR5. Furthermore, the second light emitting elements LD2 may be arranged in a zigzag pattern in the first diagonal direction DR4 and the second diagonal direction DR5. For example, the third light emitting elements LD3 may be arranged in a zigzag pattern in the first diagonal direction DR4 and the second diagonal direction DR5. For example, the light emitting elements LD may be arranged diagonally similar to the anodes AE.

The light emitting elements LD may be arranged at regular intervals in the first diagonal direction DR4 or may be arranged to have constant distances between light emitting elements LD. For example, a distance d between the first light emitting element LD1 and the second light emitting element LD2 in the first diagonal direction DR4 may be the same as a distance between the second light emitting element LD2 and the third light emitting element LD3 and as a distance between the third light emitting element LD3 and the first light emitting element LD1. The distance between the light emitting elements LD in the first direction DR1 may be the same as the distance between the light emitting elements LD in the second direction DR2. However, embodiments are not limited to the aforementioned example.

FIG. 7 is a schematic sectional view taken along line I-I′ of FIG. 6.

Referring to FIGS. 6 and 7, the pixel circuit layer PCL, the display element layer DPL, and the light functional layer LFL may be sequentially disposed on the substrate SUB.

The pixel circuit layer PCL may include insulating layers, semiconductor patterns, and conductive patterns that are stacked on the substrate SUB. The foregoing structure will be described below with reference to FIGS. 10 to 12.

The first anode AE1 and the cathode CE may be disposed on the pixel circuit layer PCL.

The first anode AE1 may be connected (e.g., electrically connected) to a transistor T_SP1 (refer to FIG. 10) of the pixel circuit layer PCL.

The cathode CE may be spaced apart from the first anode AE1 in a second diagonal direction DR5. The cathode CE may be connected (e.g., electrically connected) to the second power voltage node VSSN of FIG. 2. Accordingly, a second power voltage applied to the second power voltage node VSSN may be transmitted to the cathode CE.

A first bank BNK1 may be disposed on the first anode AE1 and the cathode CE (or the first line component CE1). The first bank BNK1 may include a first opening OP1 through which portions of the first anode AE1 and the cathode CE are exposed. The first light emitting element LD1 may be disposed in the first opening OP1 of the first bank BNK1. For example, the first bank BNK1 may be provided as a pixel defining layer that defines an area where the first light emitting element LD1 is positioned.

The first bank BNK1 may include light blocking material to prevent light mixture between adjacent sub-pixels. In embodiments, the first bank BNK1 may include organic material. For example, the first bank BNK1 may include organic insulating material made of material such as acryl resin, epoxy resin, phenol resin, polyamide resin, polyimide resin, or the like.

A first reflective electrode RFE1 may be disposed on the exposed portion of the first anode AE1 and a side surface of the first bank BNK1 adjacent thereto. A second reflective electrode RFE2 may be disposed on the exposed portion of the cathode CE and a side surface of the first bank BNK1 adjacent thereto. The first and second reflective electrodes RFE1 to RFE2 may include conductive materials suitable for reflecting light. Consequently, the light output efficiency of the first light emitting element LD1 may be enhanced. In embodiments, the first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from among the aforementioned materials. However, embodiments are not limited thereto.

The first light emitting element LD1 may be connected (e.g., electrically connected) to the first anode AE1 through the first reflective electrode RFE1. The first light emitting element LD1 may be connected (e.g., electrically connected) to the cathode CE through the second reflective electrode RFE2. The first light emitting element LD1 may be bonded to the first and second reflective electrodes RFE1 and RFE2.

The first light emitting element LD1 may include a first semiconductor layer 11, an active layer 12, a second semiconductor layer 13, and an auxiliary layer 15. The first light emitting element LD1 may include an emission stack in which the auxiliary layer 15, the first semiconductor layer 11, the active layer 12, and the second semiconductor layer 13 are sequentially stacked.

The first light emitting element LD1 may include first and second bonding electrodes BDE1 and BDE2 oriented in the same direction (e.g., in a direction opposite to the third direction DR3). The first bonding electrode BDE1 may be connected to the second semiconductor layer 13. The second bonding electrode BDE2 may be connected to the first semiconductor layer 11 exposed by etching the second semiconductor layer 13 and the active layer 12. For example, the first light emitting element LD1 may be a flip-chip-type light emitting element.

The first semiconductor layer 11 may provide electrons to the active layer 12. The first semiconductor layer 11 may include, for example, at least one n-type semiconductor layer. For example, the first semiconductor layer 11 may include any one semiconductor material among gallium nitride (GaN), aluminum gallium nitride (AlGaN), indium gallium nitride (InGaN), and aluminum nitride (AlN), and may be an n-type semiconductor layer doped with a first conductive dopant (or n-type dopant) such as silicon (Si), germanium (Ge), or tin (Sn). However, the material for forming the first semiconductor layer 11 is not limited to the aforementioned example, and various other materials may be used to form the first semiconductor layer 11. In an embodiment, the first semiconductor layer 11 may include gallium nitride (GaN) semiconductor material doped with a first conductive dopant (or an n-type dopant). In an embodiment, the first semiconductor layer 11 along with the auxiliary layer 15 may form an n-type semiconductor layer.

The active layer 12 may be disposed on the first semiconductor layer 11, and may be an area where electrons and holes are recombined with each other. As electrons and holes are recombined with each other in the active layer 12, the electrons and holes make a transition to a low energy level, light having a corresponding wavelength may be generated. The active layer 12 may have a single well structure or a multi-quantum well structure. In case that the active layer 12 is formed to have a multi-quantum well structure, units each including a barrier layer, a stain reinforcing layer, and a well layer may be repeatedly stacked to form the active layer 12. However, embodiments are not limited thereto.

The second semiconductor layer 13 may be disposed on the active layer 12, and may provide holes to the active layer 12. The second semiconductor layer 13 may include a semiconductor layer that differs in type from the first semiconductor layer 11. For example, the second semiconductor layer 13 may include at least one p-type semiconductor layer. For example, the second semiconductor layer 13 may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or p-type dopant) such as magnesium (Mg), zinc (Zn), calcium (Ca), strontium (Sr), barium (Ba), or the like. However, the material for forming the second semiconductor layer 13 is not limited to the aforementioned example, and various other materials may be used to form the second semiconductor layer 13. In an embodiment, the second semiconductor layer 13 may include gallium nitride (GaN) semiconductor material doped with a second conductive dopant (or a p-type dopant).

The auxiliary layer 15 may include undoped gallium nitride (GaN) semiconductor material, and may form an n-type semiconductor layer along with the first semiconductor layer 11.

The first bonding electrode BDE1 may be connected (e.g., electrically connected) to the second semiconductor layer 13. The second bonding electrode BDE2 may be connected (e.g., electrically connected) to the first semiconductor layer 11. The first and second bonding electrodes BDE1 and BDE2 may include eutectic metal.

The first light emitting element LD1 may further include an insulating layer 16 provided to cover a circumferential outer surface of the emission stack. The insulating layer 16 may prevent the active layer 12 from short-circuiting due to contact with other conductive material other than the first and second semiconductor layers 11 and 13. The insulating layer 16 may include transparent insulating material. The insulating layer 16 may expose lower surfaces of the first and second bonding electrodes BDE1 and BDE2.

The lower surface of the first bonding electrode BDE1 may contact the first reflective electrode RFE1. Accordingly, the first bonding electrode BDE1 may be connected (e.g., electrically connected) to the first anode AE1 through the first reflective electrode RFE1. The lower surface of the second bonding electrode BDE2 may contact the second reflective electrode RFE2. Accordingly, the second bonding electrode BDE2 may be connected (e.g., electrically connected) to the cathode CE through the second reflective electrode RFE2.

An overcoat layer OCL may be disposed in the first opening OP1 in which the first and second reflective electrodes RFE1 and RFE2 and the first light emitting element LD1 are disposed. The overcoat layer OCL may ensure the first light emitting element LD1 bonded to the first and second reflective electrodes RFE1 and RFE2 so as to prevent movement. Furthermore, the overcoat layer OCL may protect components disposed thereunder from foreign substances such as dust and water. For example, the overcoat layer OCL may include at least one of an inorganic insulating layer and an organic insulating layer. For instance, the overcoat layer OCL may include epoxy, but embodiments are not limited thereto.

A third passivation layer PSV3 may be disposed on the first bank BNK1 and the overcoat layer OCL. The third passivation layer PSV3 may protect components disposed thereunder and provide an even upper surface. The third passivation layers PSV3 may include the same material as any one of first and second passivation layers PSV1 and PSV2 (refer to FIG. 10), but embodiments are not limited thereto.

In embodiments, the third passivation layer PSV3 may not be disposed on an upper surface LTS of the first light emitting element LD1. The first light emitting element LD1 may protrude into the light functional layer LFL. The first light emitting element LD1 may be positioned at least partially in a second opening OP2 of a second bank BNK2. For example, a height of the upper surface LTS of the first light emitting element LD1 from the substrate SUB may be higher than that of a lowermost end RBE of a reflective layer RFL. Accordingly, light emitted from the first light emitting element LD1 may be provided to the light functional layer LFL at a relatively high rate.

The capping layer CPL may be disposed on the third passivation layer PSV3. The capping layer CPL may protect components disposed under the capping layer CPL such as the first light emitting element LD1 from external water, moisture, or the like. In embodiments, the capping layer CPL may not be disposed on the upper surface of the first light emitting element LD1. In other embodiments, the capping layer CPL may cover overall surfaces of the first light emitting element LD1 and the third passivation layer PSV3. The capping layer CPL may include at least one of silicon nitride (SiNₓ), silicon oxide (SiOₓ), silicon oxynitride (SiOₓN_{y}), and metal oxide such as aluminum oxide (AlOₓ). However, the material of the capping layer CPL may not be limited to the aforementioned example.

For example, the pixel circuit layer PCL and the display element layer DPL of the first sub-pixel SP1 (refer to FIG. 4) have been described. Each of the second and third sub-pixels SP2 and SP3 of FIG. 4 may also be formed in the same manner as the first sub-pixel SP1 unless otherwise described.

The light functional layer LFL may be disposed on the capping layer CPL. The light functional layer LFL may include the second bank BNK2, the reflective layer RFL, a fourth passivation layer PSV4, a first light conversion pattern CCP1, a low refractive layer LRL, and a color filter layer CFL.

The second bank BNK2 may be disposed on the capping layer CPL. The second bank BNK2 may overlap the first bank BNK1. The second bank BNK2 may include the second opening OP2 that overlaps the first opening OP1.

The second bank BNK2 may include light blocking material to prevent light mixture between adjacent sub-pixels. In embodiments, the second bank BNK2 may include organic material. For example, the second bank BNK2 may include organic insulating material made of material such as acryl resin, epoxy resin, phenol resin, polyamide resin, polyimide resin, or the like.

The reflective layer RFL may be disposed on sidewalls of the second bank BNK2 adjacent to the second opening OP2. The reflective layer RFL may reflect incident light, thereby enhancing the light output efficiency. The reflective layer RFL may include material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from among the aforementioned materials. However, embodiments are not limited thereto.

The fourth passivation layer PSV4 may be disposed on the capping layer CPL in the second opening OP2. The fourth passivation layer PSV4 may protect components disposed thereunder and may provide an even upper surface. The fourth passivation layer PSV4 may include the same material as any one of the first to third passivation layers PSV1 to PSV3, but embodiments are not limited thereto.

The first light conversion pattern CCP1 may be disposed on the fourth passivation layer PSV4 in the second opening OP2.

The first light conversion pattern CCP1 may include color conversion particles and/or scattering particles. The color conversion particles may change the wavelength of incident light and convert the incident light into light in a different color. Furthermore, the color conversion particles may scatter the incident light. In embodiments, the color conversion particles may be quantum dots. The scattering particles may scatter incident light.

The first sub-pixel SP1 may be a red sub-pixel. In the case where the first light emitting element LD1 emits light in blue, the first light conversion pattern CCP1 may include first color conversion particles QD1 that convert light in blue into light in red. In the case where the first light emitting element LD1 emits light in red, the first light conversion pattern CCP1 may include scattering particles. For example, particles included in the first light conversion pattern CCP1 may be changed in various ways according to the type of the first light emitting element LD1.

The low refractive layer LRL may be disposed on the second bank BNK2, the reflective layer RFL, and the first light conversion pattern CCP1. The low refractive layer LRL may have a refractive index lower than the first light conversion pattern CCP1. The low refractive layer LRL may refract or totally reflect incident light according to an incident angle of the corresponding light. For example, the low refractive layer LRL may provide light passing through the first light conversion pattern CCP1 to the first light conversion pattern CCP1 again. Accordingly, the light conversion efficiency of the first color conversion pattern CCP1 may be improved.

The color filter layer CFL may be disposed on the low refractive layer LRL. The color filter layer CFL may include a first color filter CF1 and light blocking patterns LBP. The first color filter CF1 may overlap the first light conversion pattern CCP1. The first color filter CF1 may selectively pass light in a desired wavelength range therethrough. In the case where the first sub-pixel SP1 is a red sub-pixel, the first color filter CF1 may include a red color filter. The light blocking patterns LBP may include at least one of various kinds of light blocking materials.

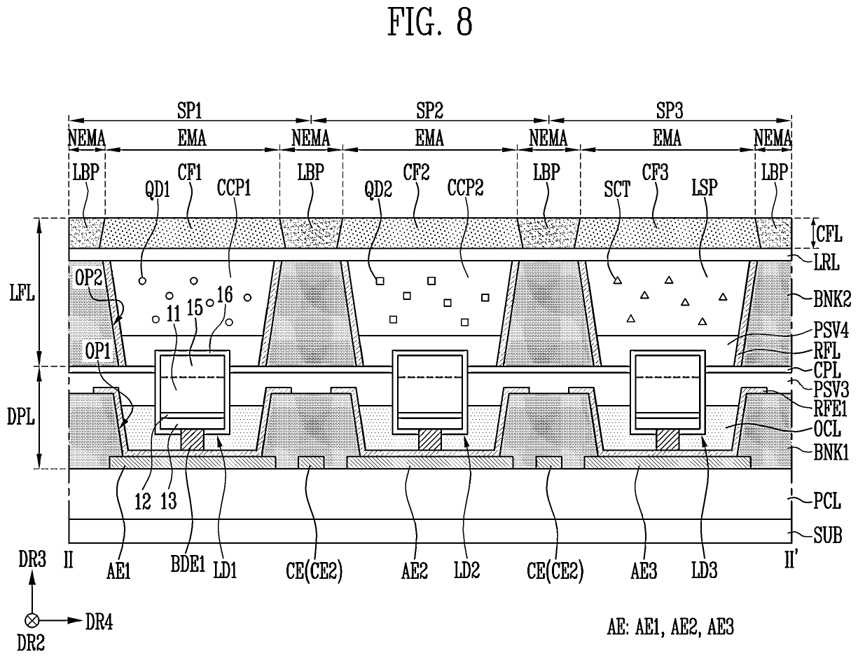

FIG. 8 is a schematic sectional view taken along line II-II′ of FIG. 6.

Referring to FIGS. 6 and 8, the pixel circuit layer PCL, the display element layer DPL, and the light functional layer LFL may be sequentially provided (or disposed) on the substrate SUB.

The pixel circuit layer PCL and the display element layer DPL are described in the same manner as described with reference to FIG. 7. Sub-pixel circuits respectively corresponding to the first to third sub-pixels SP1 to SP3 may be provided in the pixel circuit layer PCL.

In the display element layer DPL, the cathode CE (or the second line components CE2) may be provided between the anodes AE in the first diagonal direction DR4. For example, the second line components CE2 of the cathode CE may be provided between the first anode AE1 and the second anode AE2 in the first diagonal direction DR4. Furthermore, the second line components CE2 of the cathode CE may be provided between the second anode AE2 and the third anode AE3 in the first diagonal direction DR4. As the anodes AE are arranged in the first diagonal direction DR4, the distances between the anodes AE may increase, thereby allowing the cathode CE to be disposed between the anodes AE.

The first to third light emitting elements LD1 to LD3 respectively corresponding to the first to third sub-pixels SP1 to SP3 may be provided in the display element layer DPL. The first to third light emitting elements LD1 to LD3 may overlap first openings OP1 of the first bank BNK1. The first light emitting element LD1 may be connected between the cathode CE (or the first line component CE1 of FIG. 7) and the transistor T_SP1 (refer to FIG. 10) included in the sub-pixel circuit of the first sub-pixel SP1. The second light emitting element LD2 may be connected between the cathode CE and a transistor T_SP2 (refer to FIG. 11) included in the sub-pixel circuit of the second sub-pixel SP2. The third light emitting element LD3 may be connected between the cathode CE and a transistor T_SP3 (refer to FIG. 12) included in the sub-pixel circuit of the third sub-pixel SP3. Hereinafter, redundant explanations will be omitted for descriptive convenience.

The light functional layer LFL may be provided (or disposed) on the display element layer DPL. The light functional layer LFL may be described in the same manner as described with reference to FIG. 7. Hereinafter, redundant explanations will be omitted for descriptive convenience.

The second bank BNK2 may include second openings OP2. It may be understood that an emission area EMA and a non-emission area NEMA for each of the first to third sub-pixels SP1 to SP3 are defined by the second bank BNK2. An area overlapping the second bank BNK2 may correspond to (or overlap) the non-emission area NEMA. Areas overlapping the second openings OP2 of the second bank BNK2 may correspond to (or overlap) the emission areas EMA of the first to third sub-pixels SP1 to SP3.

The fourth passivation layer PSV4 may be disposed on the capping layer CPL in the second openings OP2. First and second light conversion patterns CCP1 and CCP2 and a light scattering pattern LSP may be disposed on the fourth passivation layer PSV4 in the second openings OP2.

In embodiments, the first to third light emitting elements LD1 to LD3 may emit light in blue. For example, the first light conversion pattern CCP1 may include first color conversion particles QD1 that convert light in blue into light in red. The second light conversion pattern CCP2 may include second color conversion particles QD2 that convert light in blue into light in green. The light scattering pattern LSP may include scattering particles SCT for scattering light in blue to enhance the light output efficiency. Accordingly, the first to third sub-pixels SP1 to SP3 may be provided as a red sub-pixel, a green sub-pixel, and a blue sub-pixel, respectively. In embodiments, at least one of the first and second light conversion patterns CCP1 and CCP2 and the light scattering pattern LSP may further include color conversion particles provided to convert light in blue into light in white.

In embodiments, the first to third light emitting elements LD1 to LD3 may emit light in red, green, and blue, respectively. For example, each of the first and second light conversion patterns CCP1 and CCP2 and the light scattering pattern LSP may include scattering particles SCT. For example, particles included in the first and second light conversion patterns CCP1 and CCP2 and the light scattering pattern LSP may be changed in various ways according to the first to third light emitting elements LD1 to LD3.

In another example, the first and second light conversion patterns CCP1 and CCP2 and the light scattering pattern LSP may be omitted.

The low refractive layer LRL may be disposed on the second bank BNK2, the reflective layer RFL, the first light conversion pattern CCP1, the second light conversion pattern CCP2, and the light scattering pattern LSP. The low refractive layer LRL may have a refractive index lower than the first and second light conversion patterns CCP1 and CCP2 and the light scattering pattern LSP. In embodiments, the low refractive layer LRL may be omitted in an area corresponding to the third sub-pixel SP3.

The color filter layer CFL may be disposed on the low refractive layer LRL. The color filter layer CFL may include first to third color filters CF1 to CF3 and light blocking patterns LBP.

Each of the first to third color filters CF1 to CF3 may selectively pass light in a desired wavelength range therethrough. In the case where the first sub-pixel SP1 is a red sub-pixel, the first color filter CF1 may include a red color filter. In the case where the second sub-pixel SP2 is a green sub-pixel, the second color filter CF2 may include a green color filter. In the case where the third sub-pixel SP3 is a blue sub-pixel, the third color filter CF3 may include a blue color filter. Each of the first to third color filters CF1 to CF3 may have a refractive index higher than the low refractive layer LRL. However, embodiments are not limited to the aforementioned example, and each of the first to third color filters CF1 to CF3 may have a refractive index equal to or lower than the low refractive layer LRL.

The light blocking patterns LBP may be disposed between the first to third color filters CF1 to CF3. It may be understood that an emission area (or light output area) EMA and a non-emission area NEMA for each of the first to third sub-pixels SP1 to SP3 are defined by the light blocking patterns LBP. An area overlapping the light blocking patterns LBP may correspond to (or overlap) the non-emission area NEMA. An area that does not overlap the light blocking patterns LBP may correspond to (or overlap) the emission area EMA.

In embodiments, the light blocking patterns LBP may include at least one of various kinds of light blocking materials. In embodiments, each of the light blocking patterns LBP may be provided in the form of a multilayer structure in which at least two color filters of the first to third color filters CF1 to CF3 overlap each other. For example, each of the light blocking patterns LBP may be formed by overlapping the first to third color filters CF1 to CF3. In another example, a light blocking pattern between the first and second color filters CF1 and CF2 among the light blocking patterns LBP may be formed in a multilayer structure in which the first and second color filters CF1 and CF2 overlap each other. A light blocking pattern between the second and third color filters CF2 and CF3 among the light blocking patterns LBP may be formed in a multilayer structure in which the second and third color filters CF2 and CF3 overlap each other. A light blocking pattern between the first color filter CF1 and a third color filter CF3 of a neighboring pixel may be formed in a multilayer structure in which the first and third color filters CF1 and CF3 overlap each other. For example, each of the first to third color filters CF1 to CF3 may extend to the non-emission area NEMA, thereby forming the light blocking patterns LBP.

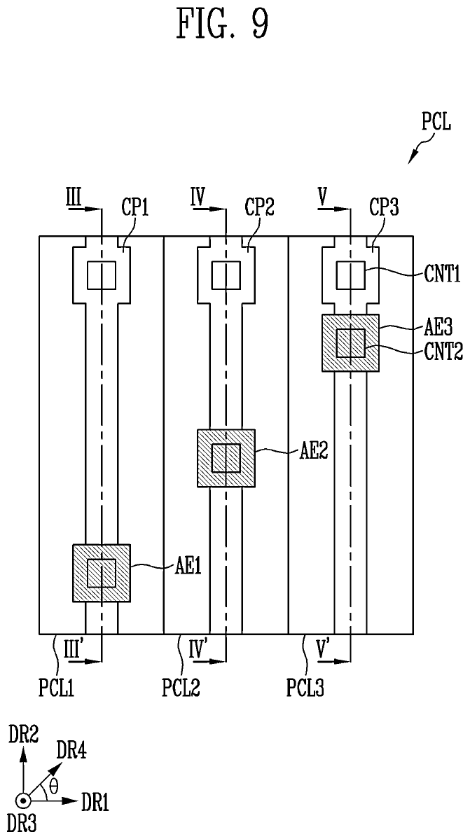

FIG. 9 is a schematic plan view illustrating a pixel circuit layer PCL according to an embodiment. For convenience of explanation, FIG. 9 illustratively shows the pixel circuit layer PCL corresponding to a single pixel PXL (refer to FIG. 4). FIG. 10 is a schematic sectional view taken along line III-III′ of FIG. 9. FIG. 11 is a schematic sectional view taken along line IV-IV′ of FIG. 9. FIG. 12 is a schematic sectional view taken along line V-V′ of FIG. 9.

Referring to FIGS. 9 to 12, the pixel circuit layer PCL may include insulating layers, semiconductor patterns, and conductive patterns that are stacked on the substrate SUB. The insulating layers may include a buffer layer BFL, one or more interlayer insulating layers ILD, and one or more passivation layers PSV1 and PSV2. The semiconductor patterns and the conductive patterns may be positioned between the insulating layers. The conductive patterns may include at least one material of copper (Cu), molybdenum (Mo), tungsten (W), aluminum-neodymium (AlNd), titanium (Ti), aluminum (Al), and silver (Ag).

The semiconductor patterns and the conductive patterns included in the pixel circuit layer PCL may function as the transistors and the capacitors of the sub-pixel circuit SPC (refer to FIG. 2). Furthermore, the conductive patterns of the pixel circuit layer PCL may also function as lines, for example, the first to m-th gate lines GL1 to GLm, the first to n-th data lines DL1 to DLn, the power lines PL, and the pixel control lines PXCL of FIG. 1.

The pixel circuit layer PCL may include a first pixel circuit layer PCL1, a second pixel circuit layer PCL2, and a third pixel circuit layer PCL3. The first pixel circuit layer PCL1 may correspond to (or overlap) the first sub-pixel SP1 (refer to FIG. 4). The second pixel circuit layer PCL2 may correspond to (or overlap) the second sub-pixel SP2 (refer to FIG. 4). The third pixel circuit layer PCL3 may correspond to (or overlap) the third sub-pixel SP3 (refer to FIG. 4).

The buffer layer BFL may be disposed on a surface of the substrate SUB. The buffer layer BFL may prevent impurities from diffusing into the circuit elements and the lines that are included in the pixel circuit layer PCL. The buffer layer BFL may include an inorganic insulating layer including inorganic material. In embodiments, the buffer layer BFL may include at least one of silicon nitride (SiNₓ), silicon oxide (SiOₓ), silicon oxynitride (SiOₓN_{y}), and metal oxide such as aluminum oxide (AlOₓ). The buffer layer BF may be provided in the form as a single layer or multiple layers. In case that the buffer layer BFL is provided in the form of a multilayer structure, the respective layers may be formed of the same material or different materials.

In embodiments, one or more barrier layers may be disposed between the substrate SUB and the buffer layer BFL. Each of the barrier layers may include polyimide.

Transistor T_SP1 to T_SP3 may be disposed on the buffer layer BFL. The transistor T_SP1 may be any one of the transistors of the sub-pixel circuit SPC included in the first sub-pixel SP1. The transistor T_SP2 may be any one of the transistors of the sub-pixel circuit SPC included in the second sub-pixel SP2. The transistor T_SP3 may be any one of the transistors of the sub-pixel circuit SPC included in the third sub-pixel SP3. For example, it may be understood that the transistors T_SP1 to T_SP3 are transistors respectively connected to the first to third anodes AE1 to AE3.

Each of the transistors T_SP1 to T_SP3 may include a semiconductor pattern SCP, a gate electrode GE, a first terminal ET1, and a second terminal ET2. The first terminal ET1 may be either a source electrode or a drain electrode, and the second terminal ET2 may be the other one of the source electrode and the drain electrode. For example, the first terminal ET1 may be a source electrode, and the second terminal ET2 may be a drain electrode.

The semiconductor pattern SCP may be disposed on the buffer layer BFL. The semiconductor pattern SCP may include a first contact area that contacts the first terminal ET1, and a second contact area that contacts the second terminal ET2. An area between the first contact area and the second contact area may be a channel area. The channel area may overlap the gate electrode GE of the transistor T_SP1. The channel area may be an undoped semiconductor pattern, and may be an intrinsic semiconductor. Each of the first contact area and the second contact area may be a semiconductor pattern doped with an impurity. For example, a p-type impurity may be used as the impurity, but embodiments are not limited thereto.

The semiconductor pattern SCP may include any one of various types of semiconductors, for example, an amorphous silicon semiconductor, a monocrystalline silicon semiconductor, a polycrystalline silicon semiconductor, a low temperature poly silicon semiconductor, and an oxide semiconductor.

The interlayer insulating layers ILD that are sequentially stacked may be disposed on the semiconductor pattern SCP. The interlayer insulating layers ILD may be formed of inorganic insulating layers including inorganic material. For example, each of the interlayer insulating layers ILD may include at least one of silicon nitride (SiNₓ), silicon oxide (SiOₓ), silicon oxynitride (SiOₓN_{y}), and metal oxide such as aluminum oxide (AlOₓ). However, the material of the interlayer insulating layers ILD is not limited to the aforementioned examples. For example, any one of the interlayer insulating layers ILD may include an organic insulating layer including organic material.

The interlayer insulating layers ILD may electrically separate the conductive patterns and/or semiconductor patterns that are disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be disposed on the overall surfaces of the semiconductor pattern SCP and the buffer layer BFL, thereby covering the semiconductor pattern SCP and the buffer layer BFL. As the number of layers needed to form the conductive patterns and/or the semiconductor patterns increases, the number of interlayer insulating layers ILD may increase.

The gate electrode GE may be disposed on the gate insulating layer GI. The gate electrode GE may overlap the channel area of the semiconductor pattern SCP. In embodiments, the gate electrode GE may be provided in the form of a single layer including at least one material of copper (Cu), molybdenum (Mo), tungsten (W), aluminum-neodymium (AlNd), titanium (Ti), aluminum (Al), and silver (Ag). In embodiments, the gate electrode GE may be provided in the form of a multilayer structure including at least one material of molybdenum (Mo), titanium (Ti), copper (Cu), aluminum (Al), and silver (Ag) that are low-resistance materials.

The first and second terminals ET1 and ET2 may be disposed on the interlayer insulating layers ILD. The first and second terminals ET1 and ET2 may contact the semiconductor pattern SCP through contact holes passing through the interlayer insulating layers ILD. The first and second terminals ET1 and ET2 may respectively contact the first and second contact areas of the semiconductor pattern SCP. Each of the first and second terminals ET1 and ET2 may include at least one material of copper (Cu), molybdenum (Mo), tungsten (W), aluminum-neodymium (AlNd), titanium (Ti), aluminum (Al), and silver (Ag).

Although the first and second terminals ET1 and ET2 are illustrated as separate electrodes connected (e.g., electrically connected) to the semiconductor pattern SCP, embodiments are not limited thereto. In embodiments, the first terminal ET1 may be a first contact area adjacent to a side of the channel area of the semiconductor pattern SCP, and the second terminal ET2 may be a second contact area adjacent to the other side of the channel area. For example, the first terminal ET1 may be connected (e.g., electrically connected) to the light emitting element LD through a connector such as a bridge electrode disposed on at least one of the interlayer insulating layers ILD.

In embodiments, each of the transistors T_SP1 to T_SP3 may be formed as a low-temperature poly-silicon transistor. However, embodiments are not limited to the aforementioned example. For example, each of the transistors T_SP1 to T_SP3 may be formed as an oxide semiconductor transistor. In embodiments, the sub-pixel circuit of each of the first to third sub-pixels SP1 to SP3 may include different types of transistors. For example, the transistors T_SP1 to T_SP3 may be formed as low-temperature poly-silicon transistors, and the other transistors may be formed as oxide semiconductor transistors. For example, an oxide semiconductor of the corresponding oxide semiconductor transistor may be disposed on any one of the interlayer insulating layers ILD rather than on an insulating layer on which the semiconductor patterns SCP of the transistors T_SP1 to T_SP3 are disposed.

Although in the embodiments the case where each of the transistors T_SP1 to T_SP3 has a top gate structure has been described as an example, embodiments are not limited thereto. For example, each of the transistors T_SP1 to T_SP3 may be a transistor having a bottom gate structure. For example, the structure of each of the transistors T_SP1 to T_SP3 may be changed in various ways.

At least some of the various lines for the display panel DP and/or the display device DD may be further disposed on the interlayer insulating layers ILD.

The first passivation layer PSV1 may be disposed on the interlayer insulating layers ILD and the first and second terminals ET1 and ET2. The passivation layer may be referred to as a protective layer or a via layer. The first passivation layer PSV1 may protect components disposed thereunder and provide an even upper surface.

The first to third conductive patterns CP1 to CP3 may be disposed on the first passivation layer PSV1. The first to third conductive patterns CP1 to CP3 may pass through the first passivation layer PSV1 and respectively connect to the first terminals ET1 of the transistors T_SP1 to T_SP3. For example, the first to third conductive patterns CP1 to CP3 may be respectively connected to the first terminals ET1 of the transistors T SP1 to T SP3 through first contact holes CNT1. Each of the first to third conductive patterns CP1 to CP3 may include at least one material of copper (Cu), molybdenum (Mo), tungsten (W), aluminum-neodymium (AlNd), titanium (Ti), aluminum (Al), and silver (Ag).

In an embodiment, the first contact holes CNT1 may have the same position in the second direction DR2 in a pixel (or in a single pixel). For example, in a single pixel PXL, the first contact holes CNT1 may be formed in the first passivation layer PSV1 at the same position in the second direction DR2.

At least some of the various lines for the display panel DP and/or the display device DD may be further disposed on the first passivation layer PSV1.

The second passivation layer PSV2 may be disposed on the first to third conductive patterns CP1 to CP3 and the first passivation layer PSV1. The second passivation layer PSV2 may protect components disposed thereunder and provide an even upper surface.

The first to third anodes AE1 to AE3 may be disposed on the second passivation layer PSV2. The first to third anodes AE1 to AE3 may pass through the second passivation layer PSV2 and respectively connect to the first to third conductive patterns CP1 to CP3. For example, the first to third anodes AE1 to AE3 may be respectively connected to the first to third conductive patterns CP1 to CP3 through the second contact holes CNT2.

In an embodiment, the second contact holes CNT2 may have different positions in the second direction DR2 in a pixel (or in a single pixel). For example, in a single pixel PXL, the second contact holes CNT2 may be formed in the second passivation layer PSV2 at different positions in the second direction DR2. The distance between the second contact holes CNT2 and the first contact holes CNT1 may be reduced in a direction from the first pixel circuit layer PCL1 to the third pixel circuit layer PCL3.

Each of the first and second passivation layers PSV1 and PSV2 may include an inorganic insulating layer including inorganic material, and/or an organic insulating layer including organic material. The inorganic insulating layer may include, for example, at least one of silicon oxide (SiOₓ), silicon nitride (SiNₓ), silicon oxynitride (SiOₓN_{y}), and metal oxide such as aluminum oxide (AlOₓ). The organic insulating layer may include, for example, at least one of acrylic resin, epoxy resin, phenol resin, polyamide resin, polyimide rein, unsaturated polyester resin, poly-phenylen ether resin, poly-phenylene sulfide resin, and benzocyclobutene resin.

The first and second passivation layers PSV1 and PSV2 may include the same material as any one of the interlayer insulating layers ILD, but embodiments are not limited thereto. Each of the first and second passivation layers PSV1 and PSV2 may be provided in the form of a single-layer structure, but may be provided in the form of a multilayer structure.

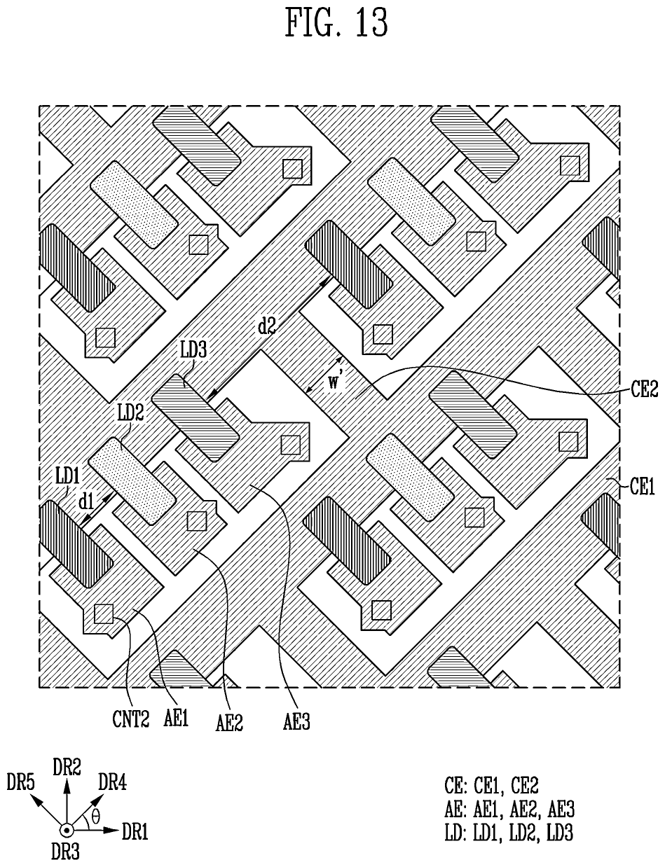

FIG. 13 is a schematic plan view illustrating a display panel DP of FIG. 4 according to an embodiment. With regard to FIG. 13, the explanation of contents overlapping that of FIG. 6 is simplified or omitted for descriptive convenience.

Referring to FIG. 13, the anodes AE may be arranged in a zigzag pattern in the first diagonal direction DR4 and the second diagonal direction DR5. However, the cathode CE may not be disposed between some anodes among the anodes AE. Therefore, the distances between the anodes AE in the first diagonal direction DR4 may not be constant. For example, in the first diagonal direction DR4, the distance between the first anode AE1 and the second anode AE2 may be the same as the distance between the second anode AE2 and the third anode AE3, and may be different from the distance between the third anode AE3 and the first anode AE1. The shape of the anodes AE may be changed according to the positions of the second contact holes CNT2.

The cathode CE may have a diagonal mesh structure, and may surround (or enclose) the anodes AE based on multiple units. For example, the cathode CE may surround (or enclose) the first to third anodes AE1 to AE3. For example, the cathode CE may not be disposed between the first anode AE1 and the second anode AE2. Furthermore, the cathode CE may not be disposed between the second anode AE2 and the third anode AE3. The cathode CE having a diagonal mesh structure may include openings. The first to third anodes AE1 to AE3 may be respectively disposed in the openings. The openings may refer to space formed by intersection of the first line components CE1 and the second line components CE2. For example, the cathode CE may surround (or enclose) the anodes AE in a pixel (or in a single pixel). For example, each of the pixels PXL (refer to FIG. 4) may have one second line component CE2.

A width w′ of the second line component CE2 of the cathode CE illustrated in FIG. 13 may be greater than the width w of the second line component CE2 of the cathode CE illustrated in FIG. 6. For example, the width w′ of the second line component CE2 of the cathode CE illustrated in FIG. 13 may be greater than three times (3*w) the width w of the second line component CE2 of the cathode CE illustrated in FIG. 6. Therefore, the effect of the voltage drop (IR drop) due to a decrease in resistance of the cathode CE may further increase.

In correspondence with the arrangement of the anodes AE, the distances between the light emitting elements LD in the first diagonal direction DR4 may not be constant. For example, a distance d1 between the first light emitting element LD1 and the second light emitting element LD2 in the first diagonal direction DR4 may be the same as a distance d1 between the second light emitting element LD2 and the third light emitting element LD3, and may be different from a distance d2 between the third light emitting element LD3 and the first light emitting element LD1. The distance d2 between the third light emitting element LD3 and the first light emitting element LD1 may be greater than the distance d1 between the first light emitting element LD1 and the second light emitting element LD2. For example, the distances d1 between the first, second, and third light emitting elements LD1, LD2, and LD3 included in a single pixel PXL (refer to FIG. 4) may be different from the distance d2 between the light emitting elements (e.g., LD1 and LD3) included in adjacent pixels.

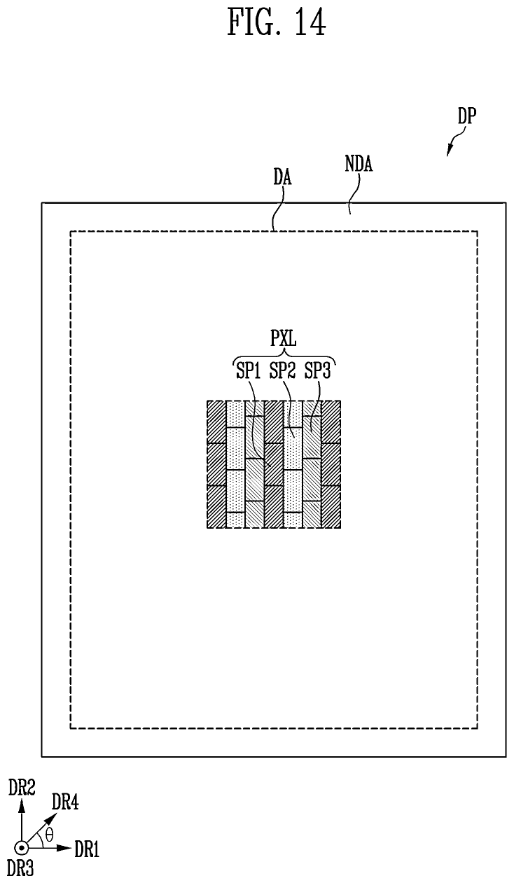

FIG. 14 is a schematic plan view illustrating a display panel DP of FIG. 1 according to an embodiment. With regard to FIG. 14, the explanation of contents overlapping that of FIG. 4 is simplified or omitted for descriptive convenience.

Referring to FIG. 14, the first sub-pixels SP1 may be arranged in the first direction DR1 and the second direction DR2 intersecting the first direction DR1. The second sub-pixels SP2 may be arranged in the first direction DR1 and the second direction DR2 intersecting the first direction DR1. The third sub-pixels SP3 may be arranged in the first direction DR1 and the second direction DR2 intersecting the first direction DR1. For example, unlike FIG. 4, the first to third sub-pixels SP1 to SP3 may be arranged in a stripe pattern.

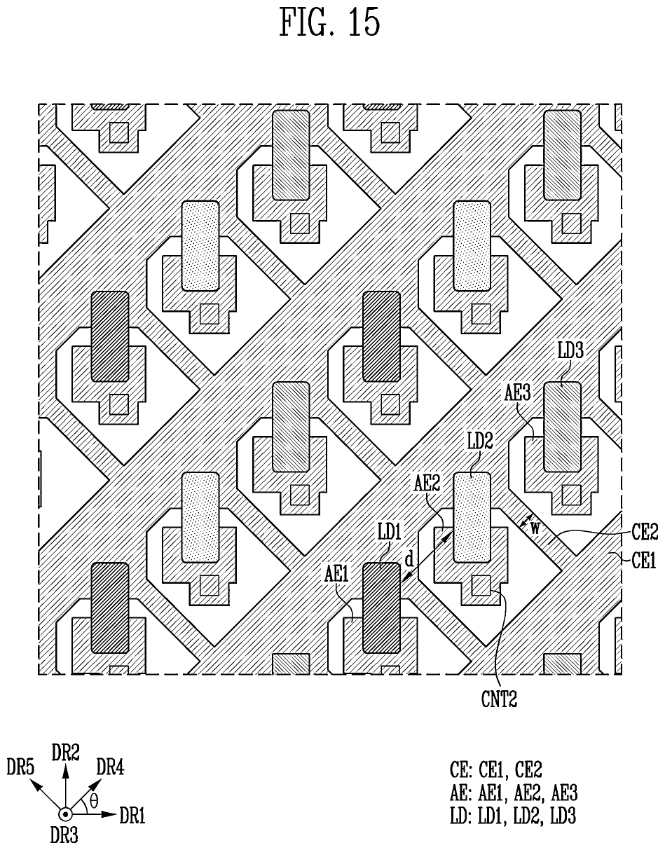

FIG. 15 is a schematic plan view illustrating a display panel DP of FIG. 14 according to an embodiment. With regard to FIG. 15, the explanation of contents overlapping that of FIG. 6 is simplified or omitted for descriptive convenience.

Referring to FIG. 15, the first light emitting elements LD1 may be arranged in the first direction DR1 and the second direction DR2 intersecting the first direction DR1. The second light emitting elements LD2 may be arranged in the first direction DR1 and the second direction DR2 intersecting the first direction DR1. The third light emitting elements LD3 may be arranged in the first direction DR1 and the second direction DR2 intersecting the first direction DR1. For example, unlike FIG. 6, the first to third light emitting elements LD1 to LD3 may be arranged in a stripe pattern. For example, a margin in the arrangement of the cathode CE may be ensured. In correspondence with a change in the arrangement of the first to third light emitting elements LD1 to LD3, the anodes AE and the cathode CE may be changed in shape. For example, the distance d between the light emitting elements LD and the width w of the second line component CE2 in the first diagonal direction DR4 may be substantially the same as those of the embodiment illustrated in FIG. 6.

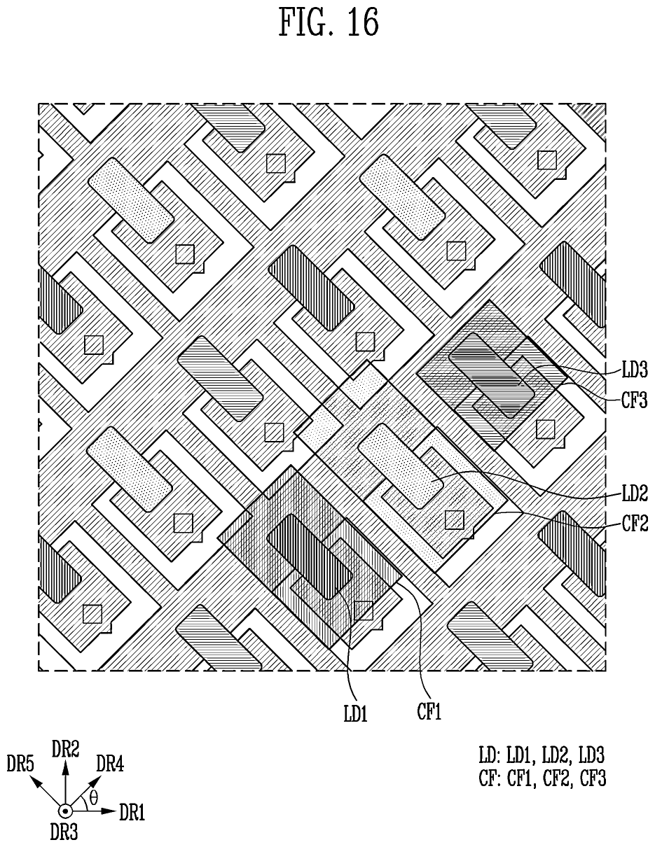

FIG. 16 is a schematic plan view illustrating a color filter layer CFL according to an embodiment. For convenience of explanation, some color filters CF1 to CF3 of the color filter layer CFL (refer to FIG. 7) are shown for illustrative purposes.

Referring to FIG. 16, the color filter CF may include a first color filter CF1, a second color filter CF2, and a third color filter CF3. In an embodiment, the first to third color filters CF1 to CF3 may be arranged in the first diagonal direction DR4 and the second diagonal direction DR5. For example, the first to third color filters CF1 to CF3 may be arranged in a diagonal shape in correspondence with the first to third light emitting elements LD1 to LD3.

In an embodiment, each of the first to third color filters CF1 to CF3 may have a rectangular shape. Short sides of each of the first to third color filters CF1 to CF3 may be parallel to the first diagonal direction DR4, and long sides thereof may be parallel to the second diagonal direction DR5.

The first to third color filters CF1 to CF3 may be respectively disposed on the first to third light emitting elements LD1 to LD3. For example, the first to third color filters CF1 to CF3 may respectively overlap the first to third light emitting elements LD1 to LD3. A center portion of the first color filter CF1 may be aligned with a center portion of the first light emitting element LD1. A center portion of the second color filter CF2 may be aligned with a center portion of the second light emitting element LD2. A center portion of the third color filter CF3 may be aligned with a center portion of the third light emitting element LD3.

In an embodiment, the sizes of the first to third color filters CF1 to CF3 may be different from each other. For example, the size of the second color filter CF2 may be greater than that of the first color filter CF1. Furthermore, the size of the first color filter CF1 may be greater than that of the third color filter CF3. For example, the size of the second color filter CF2 may be the largest, and the size of the third color filter CF3 may be the smallest.

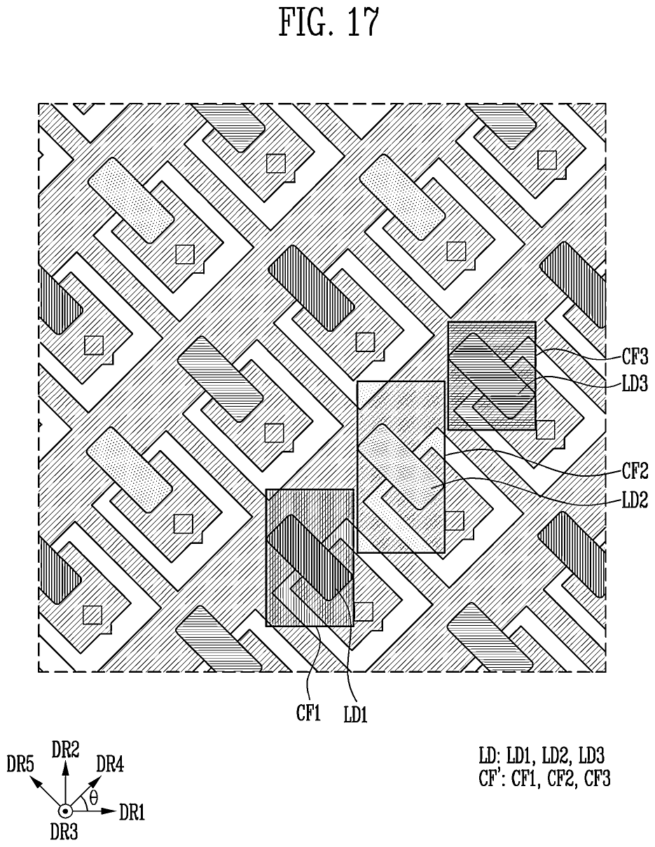

FIG. 17 is a schematic plan view illustrating a color filter layer CFL according to an embodiment. For convenience of explanation, some color filters CF1 to CF3 of the color filter layer CFL (refer to FIG. 7) are shown for illustrative purposes. With regard to FIG. 17, the explanation of contents overlapping that of FIG. 16 is simplified or omitted for descriptive convenience.

Referring to FIG. 17, the first to third color filters CF1 to CF3 may be arranged in the first direction DR1 and the second direction DR2. For example, the first to third color filters CF1 to CF3 may be arranged in a stripe shape, unlike the first to third light emitting elements LD1 to LD3.

Each of the first to third color filters CF1 to CF3 may have a rectangular shape. Short sides of each of the first to third color filters CF1 to CF3 may be parallel to the first direction DR1, and long sides thereof may be parallel to the second direction DR2. In the same manner as FIG. 16, the first to third color filters CF1 to CF3 may respectively overlap the first to third light emitting elements LD1 to LD3. Center portions of the first to third color filters CF1 to CF3 may be respectively aligned with center portions of the first to third light emitting elements LD1 to LD3.

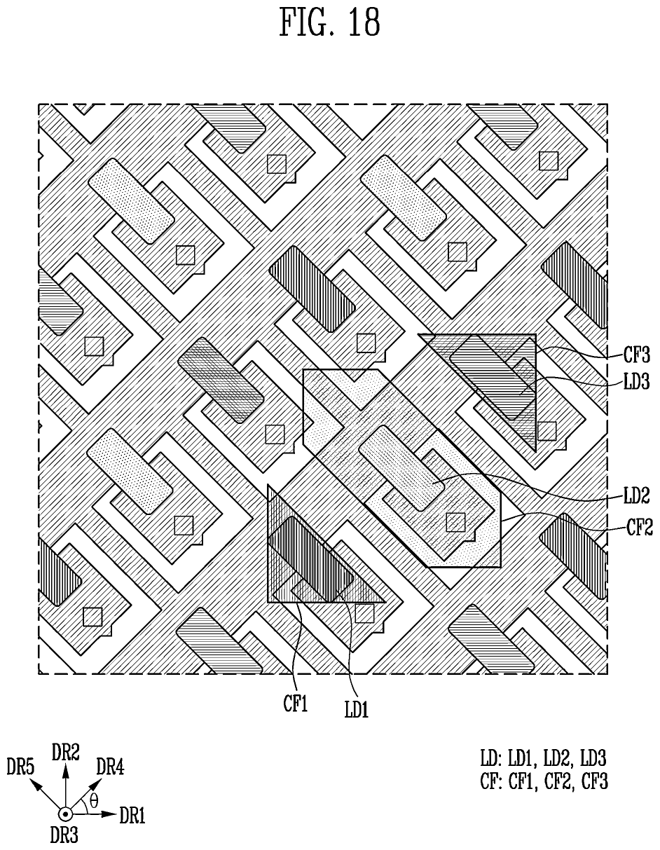

FIG. 18 is a schematic plan view illustrating a color filter layer CFL according to an embodiment. For convenience of explanation, some color filters CF1 to CF3 of the color filter layer CFL (refer to FIG. 7) are shown for illustrative purposes. With regard to FIG. 18, the explanation of contents overlapping that of FIG. 16 is simplified or omitted for descriptive convenience.

Referring to FIG. 18, the first to third color filters CF1 to CF3 may be arranged in a diagonal shape. Each of the first to third color filters CF1 to CF3 may have a polygonal shape. For example, each of the first and third color filters CF1 and CF3 may have a triangular shape, and the second color filter CF2 may have a hexagonal shape. However, embodiments are not limited to the aforementioned example.

As illustrated in FIGS. 16 to 18, the sizes, shapes, and arrangement of the first to third color filters CF1 to CF3 may be designed in various ways, taking into account characteristics (efficiency, lifespan, etc.) of the first to third light emitting elements LD1 to LD3.

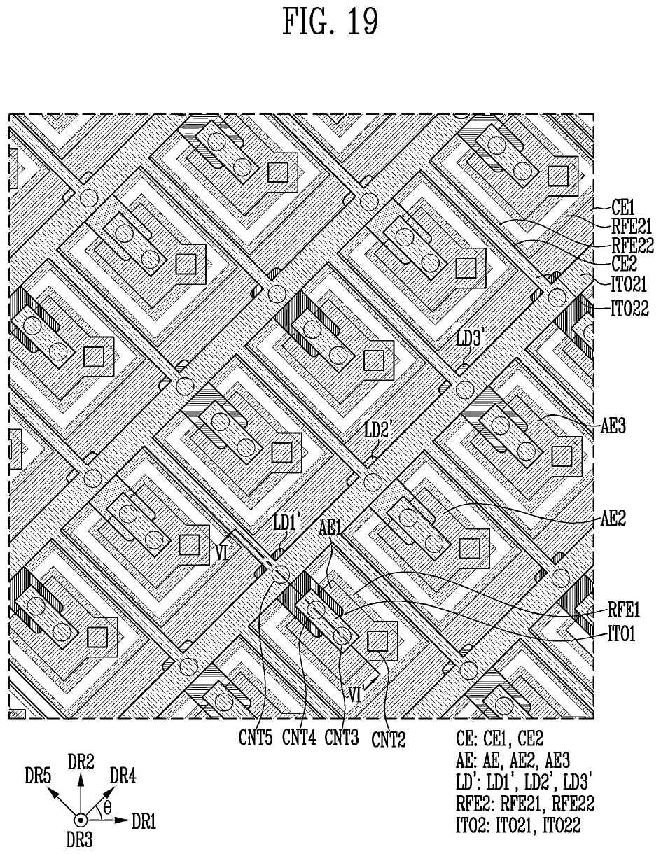

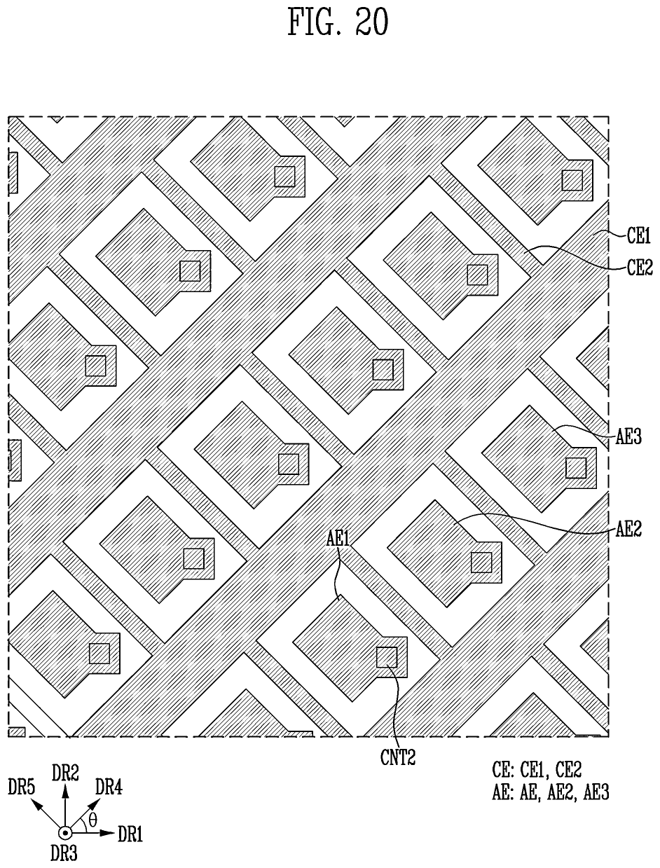

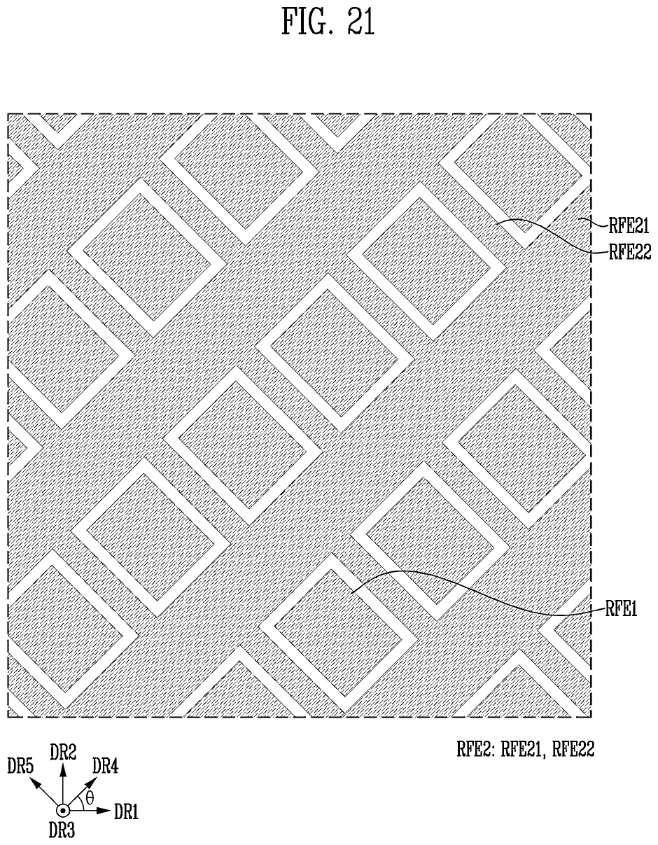

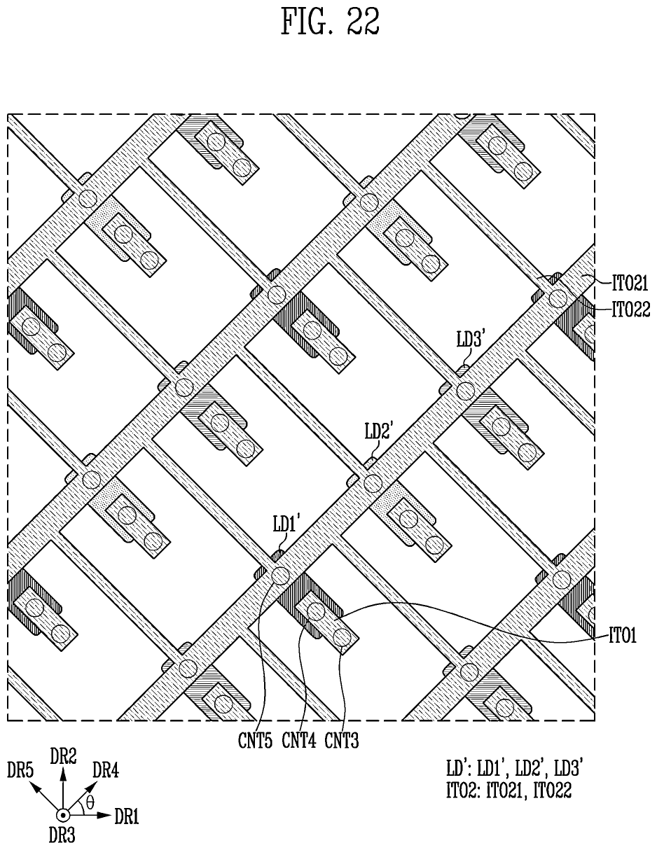

FIG. 19 is a schematic plan view illustrating a display panel DP of FIG. 4 according to an embodiment. With regard to FIG. 19, the explanation of contents overlapping that of FIG. 6 is simplified or omitted for descriptive convenience. FIG. 20 is a schematic plan view illustrating anodes AE and a cathode CE illustrated in FIG. 19. FIG. 21 is a schematic plan view illustrating first reflective electrodes RFE1 and a second reflective electrode RFE2 illustrated in FIG. 19. FIG. 22 is a schematic plan view illustrating light emitting elements LD′, first transparent electrodes ITO1, and a second transparent electrode ITO2 illustrated in FIG. 19.

Referring to FIGS. 19 and 20, the anodes AE may be arranged in a zigzag pattern in the first diagonal direction DR4 and the second diagonal direction DR5. Unlike FIG. 6, the anodes AE may be changed in shape to correspond to the positions of the second contact holes CNT2.

The cathode CE may have a diagonal mesh structure, and may include a first line component CE1 extending in the first diagonal direction DR4, and a second line component CE2 extending in the second diagonal direction DR5. Because the anodes AE and the cathode CE are the same as those described in FIG. 6, detailed descriptions thereof will be omitted for descriptive convenience.

Referring to FIGS. 19 and 21, the first reflective electrodes RFE1 may be respectively provided (or disposed) on the anodes AE. For example, the first reflective electrodes RFE1 may be respectively disposed on first anodes AE1. Furthermore, the first reflective electrodes RFE1 may be respectively disposed on second anodes AE2. For example, the first reflective electrodes RFE1 may be respectively disposed on third anodes AE3. The first reflective electrodes RFE1 may be formed to respectively cover the anodes AE.

The first reflective electrodes RFE1 may be spaced apart from each other in the first diagonal direction DR4 and the second diagonal direction DR5 intersecting the first diagonal direction DR4. For example, the first reflective electrodes RFE1 may be arranged in a zigzag pattern in the first diagonal direction DR4 and the second diagonal direction DR5.

The second reflective electrode RFE2 may be provided (or disposed) on the cathode CE. In an embodiment, the second reflective electrode RFE2 and the first reflective electrodes RFE1 may be provided (or disposed) on the same plane. The second reflective electrode RFE2 may be spaced apart from the first reflective electrodes RFE1. The second reflective electrode RFE2 may be formed to cover the cathode CE.

The second reflective electrode RFE2 may have a diagonal mesh structure. For example, the second reflective electrode RFE2 may include first electrode components RFE21 that extend in the first diagonal direction DR4 and are arranged in the second diagonal direction DR5, and second electrode components RFE22 that extend in the second diagonal direction DR5 and are arranged in the first diagonal direction DR4 and the second diagonal direction DR5. The second electrode components RFE22 may be arranged in a zigzag pattern in the first diagonal direction DR4 and the second diagonal direction DR5. The first electrode component RFE21 may be spaced apart from the light emitting elements LD in the second diagonal direction DR5. The second electrode components RFE22 may be spaced apart from the light emitting elements LD in the first diagonal direction DR4. The second reflective electrode RFE2 may surround (or enclose) each of the first reflective electrodes RFE1.

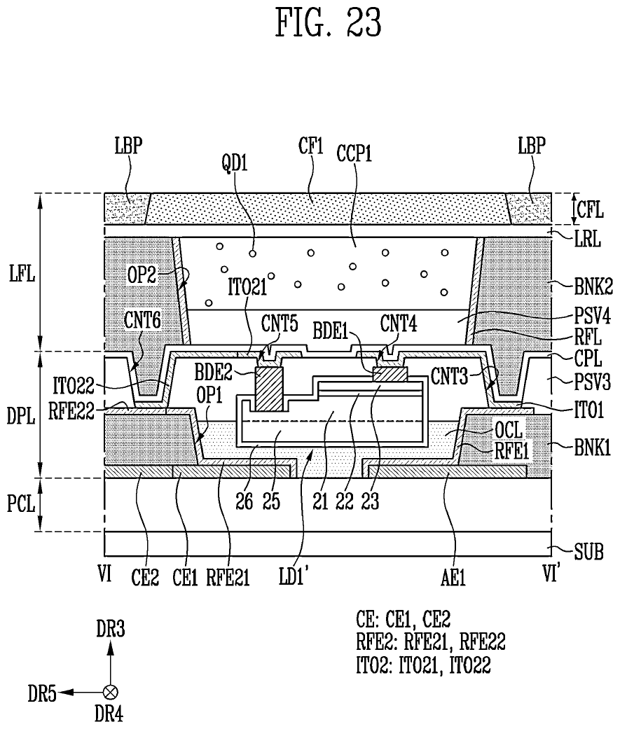

The light emitting elements LD′ may be of a lateral chip type. For example, the light emitting elements LD′ may be connected (e.g., electrically connected), on upper portions thereof, to the respective anodes AE and the cathode CE. The foregoing structure will be described herein below with reference to FIG. 23.

Referring to FIGS. 19 and 22, the first transparent electrodes ITO1 may be provided (or disposed) on the respective light emitting elements LD′ and the respective first reflective electrodes RFE1. The first transparent electrodes ITO1 may be respectively connected (e.g., electrically connected) to the first reflective electrodes RFE1 through third contact holes CNT3. Furthermore, the first transparent electrodes ITO1 may be respectively connected (e.g., electrically connected) to the light emitting elements LD′ through fourth contact holes CNT4. For example, the first transparent electrodes ITO1 provided (or disposed) on the first anodes AE1 may be respectively connected (e.g., electrically connected) to first light emitting elements LD1′ through the fourth contact holes CNT4. The first transparent electrodes ITO1 provided (or disposed) on the second anodes AE2 may be respectively connected (e.g., electrically connected) to second light emitting elements LD2′ through the fourth contact holes CNT4. The first transparent electrodes ITO1 provided (or disposed) on the third anodes AE3 may be respectively connected (e.g., electrically connected) to third light emitting elements LD3′ through the fourth contact holes CNT4.

The second transparent electrode ITO2 may be provided (or disposed) on the light emitting elements LD′ and the second reflective electrode RFE2. The second transparent electrode ITO2 and the first transparent electrodes ITO1 may be provided (or disposed) on the same plane. The second transparent electrode ITO2 may be spaced apart from the first transparent electrodes ITO1.

The second transparent electrode ITO2 may have a diagonal mesh structure. For example, the second transparent electrode ITO2 may include first transparent electrode components ITO21 that extend in the first diagonal direction DR4 and are arranged in the second diagonal direction DR5, and second transparent electrode components ITO22 that extend in the second diagonal direction DR5 and are arranged in the first diagonal direction DR4 and the second diagonal direction DR5. The second transparent electrode components ITO22 may be arranged in a zigzag pattern in the first diagonal direction DR4 and the second diagonal direction DR5. The second transparent electrode ITO2 may surround (or enclose) each of the first transparent electrodes ITO1.

The second transparent electrode ITO2 may be connected (e.g., electrically connected) to the light emitting elements LD′ through fifth contact holes CNT5. For example, the second transparent electrode ITO2 may be connected (e.g., electrically connected) to the first to third light emitting elements LD1′ to LD3′ through the fifth contact holes CNT5. Furthermore, the second transparent electrode ITO2 may be connected (e.g., electrically connected) to the second reflective electrode RFE22 through sixth contact holes CNT6 (refer to FIG. 23).

FIG. 23 is a schematic sectional view taken along line VI-VI′ of FIG. 19. With regard to FIG. 23, the explanation of contents overlapping that of FIG. 7 is simplified or omitted for descriptive convenience.

Referring to FIGS. 19 and 23, the first light emitting element LD1′ may include a first semiconductor layer 21, an active layer 22, a second semiconductor layer 23, and an auxiliary layer 25. The first light emitting element LD1′ may include an emission stack in which the auxiliary layer 25, the first semiconductor layer 21, the active layer 22, and the second semiconductor layer 23 are sequentially stacked.

The first light emitting element LD1′ may include first and second bonding electrodes BDE1 and BDE2 oriented in the same direction (e.g., in the third direction DR3). The first bonding electrode BDE1 may be connected to the second semiconductor layer 23. The second bonding electrode BDE2 may be connected to the first semiconductor layer 21 exposed by etching the second semiconductor layer 23 and the active layer 22. The first light emitting element LD1′ may be a lateral-type light emitting element.

The third passivation layer PSV3 may be disposed on the first and second reflective electrodes RFE1 and RFE2, the first light emitting element LD1′, and the overcoat layer OCL. The third passivation layer PSV3 may protect components disposed thereunder and provide an even upper surface.

The third passivation layer PSV3 may include third to sixth contact holes CNT3 to CTN6. The third contact hole CNT3 may expose a portion of the first reflective electrode RFE1. The fourth contact hole CNT4 may expose an upper surface of the first bonding electrode BDE1. The fifth contact hole CNT5 may expose a portion of the second reflective electrode RFE2. The sixth contact hole CNT6 may expose an upper surface of the second bonding electrode BDE2.

The first and second transparent electrodes ITO1 and ITO2 may be disposed on the third passivation layer PSV3. The first transparent electrode ITO1 may connect (e.g., electrically connect) the first reflective electrode RFE1 exposed through the third contact hole CNT3 to the first bonding electrode BDE1 exposed through the fourth contact hole CNT4. The second transparent electrode ITO2 may connect (e.g., electrically connect) the second reflective electrode RFE2 exposed through the sixth contact hole CNT6 to the second bonding electrode BDE2 exposed through the fifth contact hole CNT5. Accordingly, the first bonding electrode BDE1 may be connected (e.g., electrically connected) to the first anode AE1 through the first transparent electrode ITO1 and the first reflective electrode RFE1. The second bonding electrode BDE2 may be connected (e.g., electrically connected) to the cathode CE through the second transparent electrode ITO2 and the second reflective electrode RFE2.

In embodiments, the first and second transparent electrodes ITO1 and ITO2 may be substantially transparent or semitransparent to achieve (or satisfy) a specific level of light transmittance. In embodiments, the first and second transparent electrodes ITO1 and ITO2 may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the first and second transparent electrodes ITO1 and ITO2 is not limited to the aforementioned examples.

The capping layer CPL may be disposed on the third passivation layer PSV3. The capping layer CPL may protect components disposed under the capping layer CPL such as the first and second transparent electrodes ITO1 and ITO2 and the first light emitting element LD1′ from external water, moisture, or the like. The capping layer CPL may include at least one of silicon nitride (SiNₓ), silicon oxide (SiOₓ), silicon oxynitride (SiOₓN_{y}), and metal oxide such as aluminum oxide (AlOₓ). However, the material of the capping layer CPL may not be limited to the aforementioned example.

For example, the pixel circuit layer PCL and the display element layer DPL of the first sub-pixel SP1 (refer to FIG. 4) have been described. Each of the second and third sub-pixels SP2 and SP3 of FIG. 4 may also be formed in the same manner as the first sub-pixel SP1 unless otherwise described.

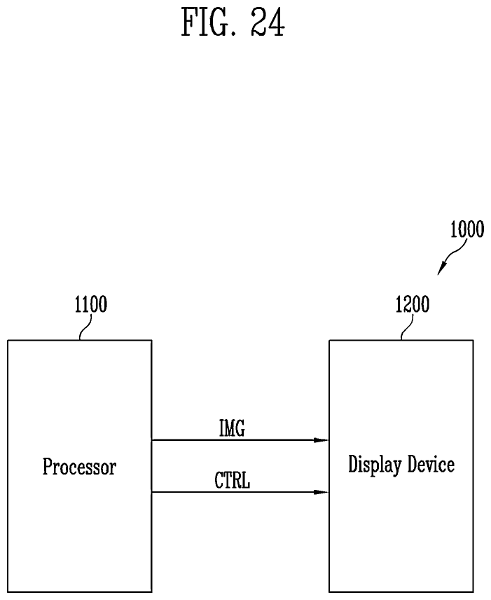

FIG. 24 is a schematic block diagram illustrating a display system 1000 according to an embodiment.

Referring to FIG. 24, the display system 1000 may include a processor 1100 and a display device 1200.

The processor 1100 may perform various tasks and operations. In embodiments, the processor 1100 may include an application processor, a graphic processor, a microprocessor, a central processing unit (CPU), and so on. The processor 1100 may be connected to the other components of the display system 1000 through a bus system to control the components.

The processor 1100 may transmit image data IMG and a control signal CTRL to the display device 1200. The display device 1200 may display an image based on the image data IMG and the control signal CTRL. The display device 1200 may be formed in the same manner as the display device DD described with reference to FIG. 1. For example, the image data IMG and the control signal CTRL may be provided as the input image data IMG and the control signal CTRL of FIG. 1, respectively.

The display system 1000 may include computing systems that provide an image display function, such as a smart watch, a mobile phone, a smart phone, a portable computer, a tablet personal computer (tablet PC), a watch phone, an automotive display, smart glasses, a portable multimedia player (PMP), a navigation system, and an ultra mobile personal computer (UMPC). Furthermore, the display system 1000 may include at least one of a head mounted display (HMD), a virtual reality (VR) device, a mixed reality (MR) device, and an augmented reality (AR) device.

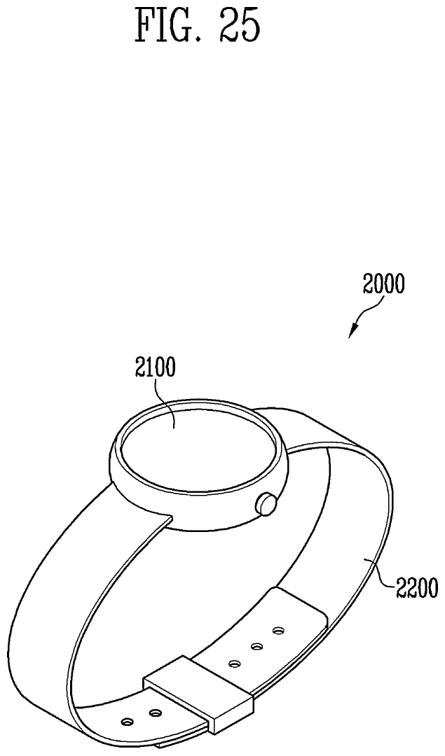

FIGS. 25 to 28 are schematic perspective views illustrating application examples of the display system 1000 of FIG. 24.

Referring to FIG. 25, the display system 1000 of FIG. 24 may be applied to a smart watch 2000 including a display component 2100 and a strap 2200.

The smart watch 2000 may be a wearable electronic device. For example, the smart watch 2000 may have a structure in which the strap 2200 may be mounted on the wrist of the user. For example, the display system 1000 and/or the display device 1200 may be applied to the display component 2100, so that image data including time information may be provided to the user.

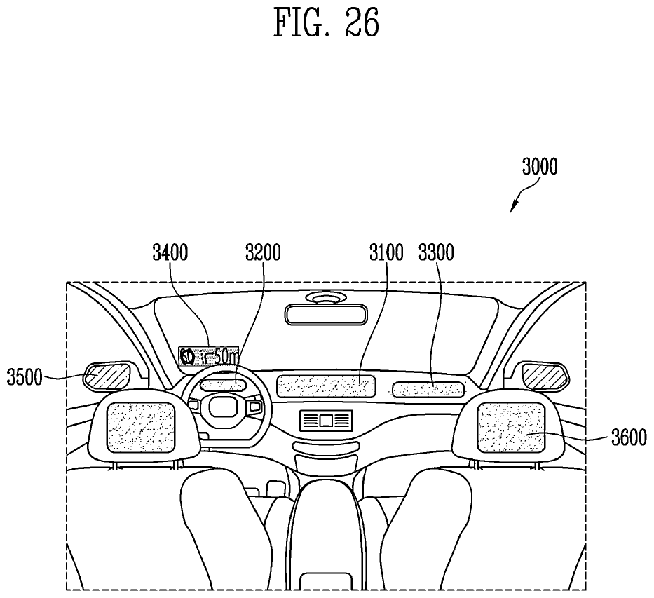

Referring to FIG. 26, the display system 1000 of FIG. 24 may be applied to the automotive display system 3000. For example, the automotive display system 3000 may include a computing system that is provided inside and/or outside a vehicle to provide image data.

For example, the display system 1000 and/or the display device 1200 may be applied to at least any one of an infotainment panel 3100, a cluster 3200, a co-driver display 3300, a head-up display 3400, a side mirror display 3500, and a rear seat display 3600, which are provided in the vehicle.

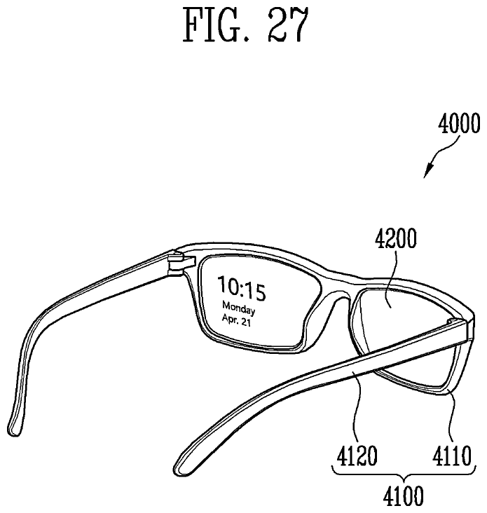

Referring to FIG. 27, the display system 1000 of FIG. 24 may be applied to smart glasses 4000. The smart glasses 4000 may be a wearable electronic device capable of being worn on the head of the user. For example, the smart glasses 4000 may be a wearable device for augmented reality.

The smart glasses 4000 may include a frame 4100 and a lens component 4200. The frame 4100 may include a housing 4110 which supports the lens component 4200, and a leg component 4120 enabling the user to wear the smart glasses. The leg component 4120 may be connected to the housing 4110 by a hinge, and thus may be folded or unfolded with respect to the housing 4110.

The frame 4100 may be equipped with a battery, a touch pad, a microphone, a camera, and the like. Furthermore, the frame 4100 may be equipped with a projector that outputs light, and a processor that controls a light signal and the like.

The lens component 4200 may include an optical component that transmits or reflects light. For example, the lens component 4200 may include glass, transparent synthetic resin, and the like.

To enable the eyes of the user to perceive visual information, the lens component 4200 may reflect images based on an optical signal transmitted from the projector of the frame 4100 by a rear surface of the lens component 4200 (e.g., a surface facing the eyes of the user). For example, the user may perceive visual information such as time and date displayed on the lens component 4200. For example, the projector and/or the lens component 4200 may be a kind of display device. The display device 1200 may be applied to the projector and/or the lens component 4200.

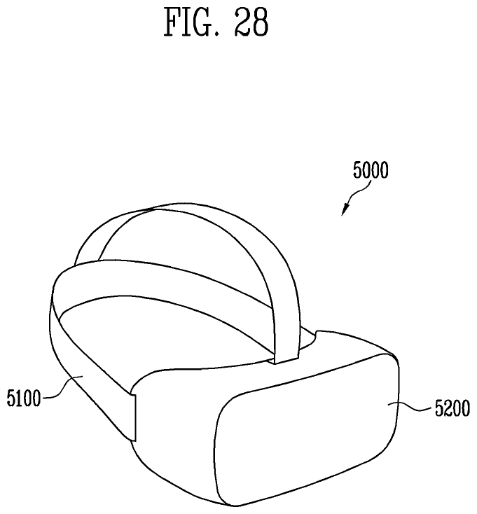

Referring to FIG. 28, the display system 1000 of FIG. 24 may be applied to a head mounted display device 5000.

The head mounted display device 5000 may be a wearable electronic device, which is worn on the head of the user. For example, the head mounted display device 5000 may be a wearable device for virtual reality or mixed reality.

The head mounted display device 5000 may include a head mounted band 5100 and a display device reception casing 5200. The head mounted band 5100 may be connected to the display device reception casing 5200. The head mounted band 5100 may include a horizontal band and/or a vertical band to fasten the head mounted display device 5000 to the head of the user. The horizontal band may surround (or enclose) the sides of the head of the user, and the vertical band may surround (or enclose) the top of the head of the user. However, embodiments are not limited to the aforementioned example. For example, the head mounted band 5100 may be implemented in the form of eyeglass frames, a helmet, and so on.

The display device reception casing 5200 may receive the display system 1000 and/or the display device 1200.

Various embodiments may provide a display device capable of mitigating voltage drop (IR drop) and power consumption.

However, effects of the disclosure are not limited to the above-described effects, and various modifications are possible without departing from the spirit and scope of the disclosure.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a pixel circuit layer;
anodes disposed on the pixel circuit layer, the anodes spaced apart from each other in a first diagonal direction and a second diagonal direction intersecting the first diagonal direction;
a cathode disposed on the pixel circuit layer, the cathode spaced apart from the anodes; and
light emitting elements,
wherein the light emitting elements are electrically connected to the anodes and the cathode.

2. The display device of claim 1, wherein the pixel circuit layer comprises:
transistors;
a first passivation layer including first contact holes;
conductive patterns arranged on the first passivation layer in a first direction, and extending in a second direction intersecting the first direction; and
a second passivation layer including second contact holes.

3. The display device of claim 2, wherein, in each pixel, the first contact holes have a same position in the second direction, and the second contact holes have different positions in the second direction.

4. The display device of claim 1, wherein the anodes and the cathode are disposed on a same plane.

5. The display device of claim 1, wherein the anodes are arranged in a zigzag pattern in the first diagonal direction and the second diagonal direction.

6. The display device of claim 1, wherein the cathode has a diagonal mesh structure.

7. The display device of claim 6, wherein the cathode comprises:
a first line component extending in the first diagonal direction and disposed in the second diagonal direction; and
a second line component extending in the second diagonal direction and disposed in a zigzag pattern in the first diagonal direction and the second diagonal direction.

8. The display device of claim 6, wherein the cathode surrounds the anodes in each sub-pixel.

9. The display device of claim 6, wherein each of the light emitting elements comprises a flip-chip-type light emitting element.

10. The display device of claim 9, wherein the light emitting elements are arranged in the first diagonal direction to have constant distances between the light emitting elements.

11. The display device of claim 10, wherein the light emitting elements are arranged in a zigzag pattern in the first diagonal direction and the second diagonal direction.

12. The display device of claim 6, wherein the cathode surrounds the anodes in each pixel.

13. The display device of claim 12, wherein
light emitting elements included in each pixel are arranged in the first diagonal direction to have first distances between the light emitting elements included in each pixel, and
light emitting elements respectively included in adjacent pixels are arranged in the first diagonal direction to have a second distance between the light emitting elements respectively included in adjacent pixels, which is different from the first distances.

14. The display device of claim 9, wherein the light emitting elements are arranged in a first direction and a second direction intersecting the first direction to have constant distances between the light emitting elements.

15. The display device of claim 1, further comprising:
color filters respectively disposed on the light emitting elements.

16. The display device of claim 15, wherein a center portion of each of the color filters is aligned with a center portion of a corresponding one of the light emitting elements.

17. The display device of claim 15, wherein
the light emitting elements comprise:
first light emitting elements that emit light in a first color,
second light emitting elements that emit light in a second color, and
third light emitting elements that emit light in a third color, and
the color filters comprise:
first color filters respectively disposed on the first light emitting elements,
second color filters respectively disposed on the second light emitting elements, and
third color filters respectively disposed on the third light emitting elements.

18. The display device of claim 17, wherein
a size of each of the second color filters is greater than a size of each of the first color filters, and
the size of each of the first color filters is greater than a size of each of the third color filters.

19. The display device of claim 15, wherein each of the color filters has a polygonal shape.

20. The display device of claim 6, wherein each of the light emitting elements comprises a lateral-chip-type light emitting element.

21. The display device of claim 20, further comprising:
a reflective electrode disposed in a diagonal mesh structure on the cathode; and
a transparent electrode disposed in a diagonal mesh structure on the reflective electrode, and electrically connected to the light emitting elements.
